(19) United States
(12) Patent Application Publication
(10) Pub. No.: US 2026/0096101 A1
(43) Pub. Date: Apr. 2, 2026

(54) SEMICONDUCTOR MEMORY DEVICE

(71) Applicant: SAMSUNG ELECTRONICS CO., LTD., Suwon-si (KR)

(72) Inventors: Kyung Hwan LEE, Overijse (BE); Sang Min KANG, Auderghem (BE); Min Tae RYU, Suwon-si (KR)

(73) Assignee: SAMSUNG ELECTRONICS CO., LTD., Suwon-si (KR)

(21) Appl. No.: 19/207,010

(22) Filed: May 13, 2025

(30) Foreign Application Priority Data
Oct. 2, 2024 (KR) 10-2024-0133780

(51) Int. Cl. H10B 51/20; H10B 51/10; H10B 51/30

(52) U.S. Cl. CPC H10B 51/20; H10B 51/10; H10B 51/30

(57) ABSTRACT

A semiconductor memory device a first conductive line in a first horizontal direction parallel to an upper surface of a substrate; a second conductive line spaced apart from the first conductive line in a second horizontal direction; a gate electrode in a vertical direction and between the first and second conductive line; a semiconductor pattern in the vertical direction and surrounding side surfaces of the gate electrode; an insertion pattern, in a ferroelectric material, extending in the vertical direction and between the gate electrode and the semiconductor pattern; a metal pattern in the vertical direction and between the insertion and the semiconductor pattern; and a gate insulating pattern in the vertical direction and between the metal and the semiconductor pattern, where an area of the insertion pattern in contact with the metal pattern is smaller than an area of the gate insulating pattern in contact with the semiconductor pattern.

### CROSS-REFERENCE TO RELATED APPLICATION

This application claims priority from Korean Patent Application No. 10-2024-0133780 filed on Oct. 2, 2024 in the Korean Intellectual Property Office, and all the benefits accruing therefrom under 35 U.S. C. 119, the contents of which in its entirety are herein incorporated by reference.

### BACKGROUND

The present disclosure relates to a semiconductor memory device.

In order to meet the consumer demand for superior performance and affordable prices, increasing the integration density of semiconductor devices is required. The integration density of semiconductor devices is an important factor that determines the product price. Accordingly, particularly higher integration density is required.

In the case of conventional two-dimensional (2D) or planar semiconductor devices, the integration density is largely determined by the area occupied by unit memory cells, and is thus greatly affected by the level of fine pattern formation technology. However, since ultra-high-cost equipment is required to achieve fine patterning, the integration density of 2D semiconductor devices is increasing, but still limited. Therefore, three-dimensional (3D) semiconductor memory devices having memory cells arranged three-dimensionally have been proposed.

### SUMMARY

Aspects of the present disclosure provide a three-dimensional (3D) semiconductor memory device with improved electrical characteristics and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an example embodiment of the present disclosure, a semiconductor memory device includes a first conductive line extending in a first horizontal direction parallel to an upper surface of a substrate; a second conductive line spaced apart from the first conductive line in a second horizontal direction, the second conductive line extending in the first horizontal direction, and the second horizontal direction being parallel to the upper surface of the substrate and intersecting the first horizontal direction; a gate electrode extending in a vertical direction perpendicular to the upper surface of the substrate and between the first conductive line and the second conductive line; a semiconductor pattern extending in the vertical direction and surrounding side surfaces of the gate electrode, the semiconductor pattern being electrically connected to the first conductive line and the second conductive line; an insertion pattern extending in the vertical direction and between the gate electrode and the semiconductor pattern, the insertion pattern comprising a ferroelectric material; a metal pattern extending in the vertical direction and between the insertion pattern and the semiconductor pattern; and a gate insulating pattern extending in the vertical direction and between the metal pattern and the semiconductor pattern, wherein an area of the insertion pattern in contact with the metal pattern is smaller than an area of the gate insulating pattern in contact with the semiconductor pattern.

According to an example embodiment of the present disclosure, a semiconductor memory device includes first conductive lines and first insulating patterns alternately stacked in a vertical direction perpendicular to an upper surface of a substrate; a gate electrode extending in the vertical direction; a plurality of semiconductor patterns surrounding side surfaces of the gate electrode, each semiconductor pattern among the plurality being spaced apart in the vertical direction; insertion patterns between the gate electrode and the plurality of semiconductor patterns; a plurality of metal patterns between the insertion patterns and the plurality of semiconductor patterns such that a respective metal pattern is between the insertion pattern and a respective semiconductor pattern; and a plurality of gate insulating patterns between the plurality of metal patterns and the plurality of semiconductor patterns such that a respective gate insulating pattern is between the respective metal pattern and the respective semiconductor pattern, wherein the first insulating patterns extend between the semiconductor patterns; wherein the semiconductor patterns are electrically connected to the respective first conductive lines, and wherein a length of the insertion patterns in contact with the metal patterns is smaller than a length of the gate insulating patterns in contact with the semiconductor patterns.

According to an example embodiment of the present disclosure, a semiconductor memory device includes a first conductive line extending in a first horizontal direction parallel to an upper surface of a substrate; a second conductive line spaced apart from the first conductive line in a second horizontal direction, the second horizontal direction also being parallel to the upper surface of the substrate and intersecting the first horizontal direction, the second conductive line extending in the first horizontal direction; gate electrodes spaced apart in the first horizontal direction and extending in a vertical direction perpendicular to the upper surface of the substrate between the first conductive line and the second conductive line; a respective semiconductor pattern extending in the first horizontal direction, surrounding side surfaces of each of the gate electrodes, and electrically connected to the first conductive line and the second conductive line; a respective insertion pattern between each of the gate electrodes and the respective semiconductor pattern, the respective insertion pattern comprising a ferroelectric material; a respective metal pattern between the respective insertion pattern and the respective semiconductor pattern; and a respective gate insulating pattern between the respective metal pattern and the respective semiconductor pattern, wherein an area of the respective insertion pattern in contact with the respective metal pattern is smaller than an area of the respective gate insulating pattern in contact with the respective semiconductor pattern.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail exemplary embodiments thereof with reference to the attached drawings, in which:

FIG. 1 is an exemplary perspective view illustrating a semiconductor memory device according to some embodiments;

FIG. 2 is a plan view illustrating a semiconductor memory device according to some embodiments;

FIG. 3 is a cross-sectional view taken along line A-A′ of FIG. 2;

FIG. 4 is a cross-sectional view taken along line B-B′ of FIG. 2;

FIGS. 5 through 8 are enlarged views of an area S1 of FIG. 3;

FIG. 9 is a diagram illustrating an insertion pattern according to some embodiments;

FIGS. 10 and 11 are cross-sectional views illustrating aspects of a semiconductor memory device according to some embodiments;

FIGS. 12 through 14 are enlarged cross-sectional views of an area S2 of FIG. 10;

FIGS. 15 through 31 are diagrams illustrating exemplary method(s) of manufacturing a semiconductor memory device according to some embodiments;

FIGS. 32 through 34 are diagrams illustrating aspects of a semiconductor memory device according to some embodiments;

FIGS. 35 through 44 are diagrams illustrating exemplary method(s) of manufacturing a semiconductor memory device according to some embodiments;

FIG. 45 is a plan view illustrating a semiconductor memory device according to some embodiments;

FIG. 46 is a cross-sectional view taken along line A-A′ of FIG. 45;

FIG. 47 is a plan view illustrating aspects of a semiconductor memory device according to some embodiments;

FIG. 48 is a cross-sectional view taken along line E-E′ of FIG. 47; and

FIGS. 49 through 51 are diagrams illustrating aspects of a semiconductor memory device according to some embodiments.

### DETAILED DESCRIPTION

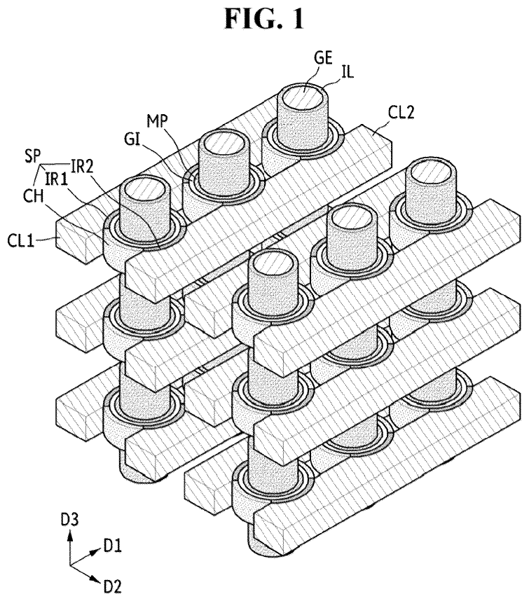

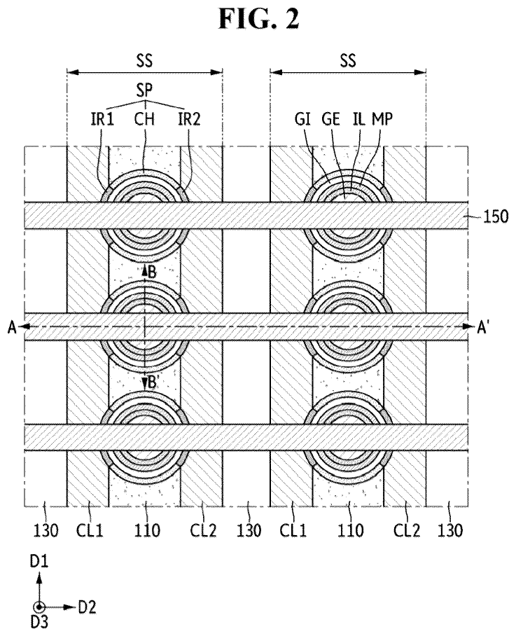

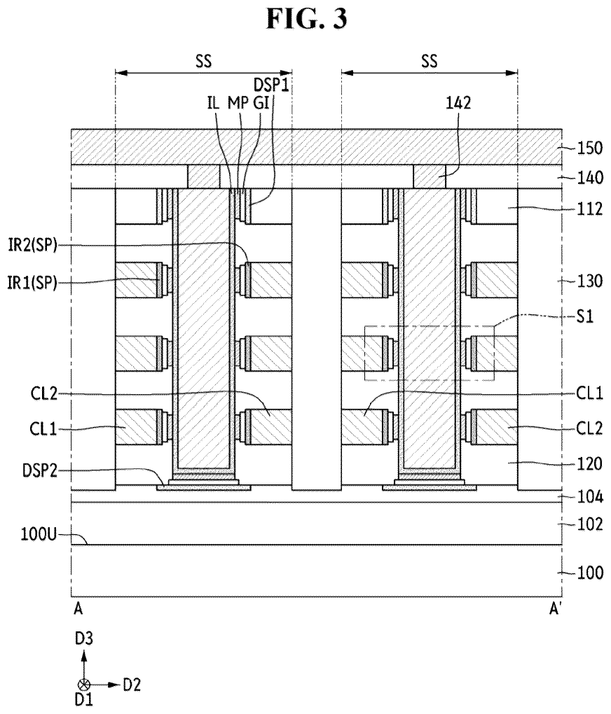

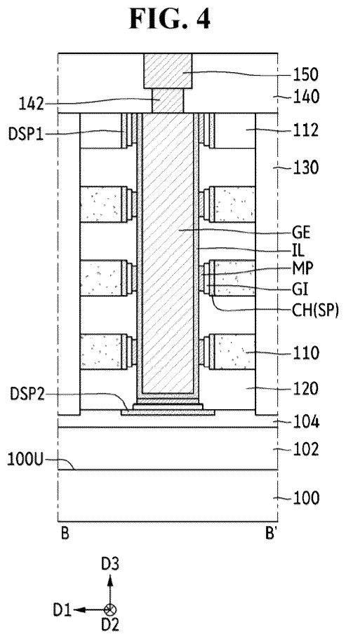

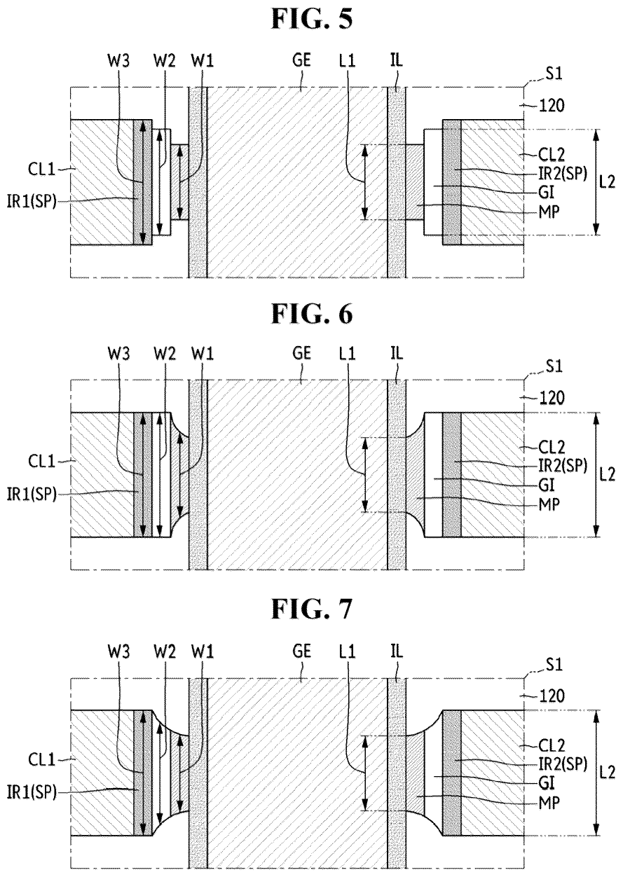

FIG. 1 is an exemplary perspective view illustrating a semiconductor memory device according to some embodiments. FIG. 2 is a plan view illustrating a semiconductor memory device according to some embodiments. FIG. 3 is a cross-sectional view taken along line A-A′ of FIG. 2. FIG. 4 is a cross-sectional view taken along line B-B′ of FIG. 2. FIGS. 5 through 8 are enlarged cross-sectional views of an area S1 of FIG. 3. FIG. 9 is a diagram for explaining an insertion pattern according to some embodiments.

Referring to FIGS. 1 through 9, the semiconductor memory device according to some embodiments may include a substrate 100, a lower insulating film 102, an etch stop film 104, stacked structures SS, a separation structure 130, an upper insulating film 140, contacts 142, and wires 150.

The substrate 100 may be a bulk silicon (Si) or silicon-on-insulator (SOI) substrate. Alternatively, the substrate 100 may be an Si substrate, or may include other materials such as silicon-germanium (SiGe), SiGe-on-insulator (SGOI), indium antimonide, a lead telluride compound, indium arsenide, indium phosphide, gallium arsenide, or gallium antimonide, but the present disclosure is not limited thereto. In embodiments, e.g., FIG. 3, first horizontal direction D1 and second horizontal direction D1 are parallel to an upper surface 100U of the substrate 100 and intersect each other. The vertical direction D3 intersects a plane formed by the first and second horizontal directions D1 and D2 and is perpendicular to the upper surface 100U of the substrate 100.

The lower insulating film 102 may be disposed on the upper surface 100U of the substrate 100. The lower insulating film 102 may include, for example, silicon oxide, silicon nitride, and/or silicon oxynitride.

The etch stop film 104 may be disposed on the lower insulating film 102, e.g., on an upper surface of lower insulating film 102. The lower insulating film 102 may be disposed between the substrate 100 and the etch stop film 104. The etch stop film 104 may include, for example, a metal oxide such as aluminum oxide.

The stacked structures SS may be disposed on the etch stop film 104. As shown in FIG. 2, the stacked structures SS may be spaced apart in the second horizontal direction D2. The stacked structure SS may include first conductive lines CL1, second conductive lines CL2, gate electrodes GE, insertion patterns IL, metal patterns MP, gate insulating patterns GI, semiconductor patterns SP, first insulating patterns 110, and second insulating patterns 120. An embodiments of the stacked structure SS will hereinafter be described as an example.

The first conductive lines CL1 may extend in the first horizontal direction D1. The first conductive lines CL1 may have a line or bar shape extending in the first horizontal direction D1. The first conductive lines CL1 may be spaced apart in the vertical direction D3.

The second conductive lines CL2 may be spaced apart from the first conductive lines CL1 with the space between them being in the second horizontal direction D2. The second conductive lines CL2 may extend in the first horizontal direction D1. The second conductive lines CL2 may have a line or bar shape extending in the first horizontal direction D1. The second conductive lines CL2 may be spaced apart in the vertical direction D3. In embodiments, the second conductive lines CL2 may be in a plane parallel to the first conductive lines CL1.

The gate electrodes GE may extend in the vertical direction D3. The gate electrodes GE may have a line or pillar shape extending in the vertical direction D3. The gate electrodes GE may be disposed between the first conductive lines CL1 and the second conductive lines CL2. The gate electrodes GE may be spaced apart in the first horizontal direction D1. The gate electrodes GE may be spaced between the first conductive lines CL1 and the second conductive lines CL2.

The first conductive lines CL1 and the second conductive lines CL2 may each include a conductive material. The first conductive lines CL1 and the second conductive lines CL2 may each include, for example, doped polysilicon, a metal, a conductive metal nitride, a conductive metal silicide, a conductive metal oxide, or a combination thereof. The first conductive lines CL1 and the second conductive lines CL2 may each include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but the present disclosure is not limited thereto. The first conductive lines CL1 and the second conductive lines CL2 may each include a two-dimensional (2D) semiconductor material, and the 2D semiconductor material may include, for example, graphene, carbon nanotube, or a combination thereof.

The gate electrodes GE may include a conductive material. The gate electrodes GE may include, for example, doped polysilicon, metal, conductive metal nitride, conductive metal silicide, conductive metal oxide, or a combination thereof. The gate electrodes GE may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but the present disclosure is not limited thereto.

The semiconductor patterns SP (e.g., as shown in FIG. 2) may be disposed between the first conductive lines CL1 and the second conductive lines CL2. The semiconductor patterns SP may surround the sides of each of the gate electrodes GE. The components, layers, and/or regions of the semiconductor patterns SP may be spaced apart in the vertical direction D3 and surround the sides of the gate electrodes GE. In a plan view, the semiconductor patterns SP may have an annular shape. The semiconductor patterns SP may extend in the first horizontal direction D1 and surround the sides of the gate electrodes GE arranged along the first horizontal direction D1.

The semiconductor patterns SP may include a semiconductor material such as Si, germanium (Ge), SiGe, silicon carbide (SiC), metal oxide, or a 2D material. For example, the semiconductor patterns SP may include polysilicon. In another example, the semiconductor patterns SP may include an amorphous metal oxide, polycrystalline metal oxide, or a combination of amorphous and polycrystalline metal oxides. Exemplary metal oxides may include but not be limited to, indium oxide, tin oxide, zinc oxide, indium-zinc oxide (IZO), tin-zinc oxide, barium-tin oxide, aluminum-zinc oxide, zinc-magnesium oxide, tin-magnesium oxide, indium-magnesium oxide, indium-gallium oxide (IGO), indium-gallium-zinc oxide (IGZO), indium-aluminum-zinc oxide, indium-tin-zinc oxide (ITZO), indium-tungsten-zinc oxide (IWZO), tin-gallium-zinc oxide, aluminum-gallium-zinc oxide, tin-aluminum-zinc oxide, indium-hafnium-zinc oxide, indium-lanthanum-zinc oxide, indium-cerium-zinc oxide, indium-praseodymium-zinc oxide, indium-neodymium-zinc oxide, indium-samarium-zinc oxide, indium-europium-zinc oxide, indium-gadolinium-zinc oxide, indium-terbium-zinc oxide, indium-dysprosium-zinc oxide, indium-holmium-zinc oxide, indium-erbium-zinc oxide, indium-thulium-zinc oxide, indium-ytterbium-zinc oxide, indium-lutetium-zinc oxide, indium-tin-gallium-zinc oxide, indium-hafnium-gallium-zinc oxide, indium-aluminum-gallium-zinc oxide, indium-tin-aluminum-zinc oxide, indium-tin-hafnium-zinc oxide, indium-hafnium-aluminum-zinc oxide, but is not limited thereto.

In another example, when the semiconductor patterns SP include a 2D material, such as but not limited to a 2D allotrope or a 2D compound. For example, the semiconductor patterns SP may include, for example, at least one of graphene, molybdenum disulfide (MoS₂), molybdenum diselenide (MoSe₂), tungsten diselenide (WSe₂), or tungsten disulfide (WS₂), but the present disclosure is not limited thereto.

The semiconductor patterns SP may include first impurity regions IR1, second impurity regions IR2, and channel regions CH between the first impurity regions IR1 and the second impurity regions IR2.

The first impurity regions IR1 may be disposed between the first conductive lines CL1 and the gate electrodes GE. The first impurity regions IR1 may be electrically connected to the first conductive lines CL1. The second impurity regions IR2 may be disposed between the second conductive lines CL2 and the gate electrodes GE. The second impurity regions IR2 may be electrically connected to the second conductive lines CL2. The first impurity regions IR1 of the semiconductor patterns SP positioned at the same level (e.g., at a same level or at a same approximate distance from the substrate 100 in the vertical direction D3) may be connected to the first conductive lines CL1. The second impurity regions IR2 of the semiconductor patterns SP positioned at the same level (e.g., at a same level or at a same approximate distance from the substrate 100 in the vertical direction D3) may be connected to the second conductive lines CL2. The channel regions CH may be interposed between the first impurity regions IR1 and the gate insulating patterns GI.

The first impurity regions IR1 and the second impurity regions IR2 may include impurities of the same conductivity type. The first impurity regions IR1 and the second impurity regions IR2 may include, for example, N-type impurities or P-type impurities.

Insertion patterns IL may be disposed between the semiconductor patterns SP and the gate electrodes GE. The insertion patterns IL may surround the sides of the respective gate electrodes GE.

The insertion patterns IL may be comprised of a ferroelectric material. The ferroelectric material may include at least one oxide selected from Hf, Si, Al, Zr, Y, La, Gd, and Sr. For example, the ferroelectric material may include an Hf oxide having dielectric properties. The ferroelectric material may further include a dopant, which may be at least one selected from Zr, Si, Al, Y, Gd, La, Sc, and Sr. The ferroelectric material may include, for example, HfO₂, HfZnO, HfSiO, HfSiON, HfTaO, HfTiO, HfZrO, or a combination thereof. The ferroelectric material may have an orthorhombic phase. In some embodiments, the insertion patterns IL may be a plurality of individual ferroelectric layers or a single ferroelectric layer.

The metal patterns MP may be disposed between the semiconductor patterns SP and the insertion patterns IL. The gate insulating patterns GI may be disposed between the semiconductor patterns SP and the metal patterns MP. The insertion patterns IL, the metal patterns MP, the gate insulating patterns GI, and the semiconductor patterns SP may be sequentially disposed along the sides of the gate electrodes GE. The order of patterns disclosed herein is exemplary and it must be understood that the disclosure is not limited thereto. Metal patterns MP and gate insulating patterns GI disposed on a single gate electrode GE may be spaced apart in the vertical direction D3.

The metal patterns MP may include a metal (e.g., Pt) and/or a metal oxide (e.g., RuO₂, IrO₂, or LaSrCoO₃). The metal patterns MP may be used to help maintain the polarization of the ferroelectric material in the insertion patterns IL. The gate insulating patterns GI may include a silicon oxide film, a silicon oxynitride film, a high-k dielectric film having a greater dielectric constant than silicon oxide, or a combination thereof. The high-k dielectric film may include a metal oxide or metal oxynitride.

In embodiments, ferroelectric field-effect transistors (FETs) may be formed and may include the semiconductor patterns SP, the gate electrodes GE corresponding to the semiconductor patterns SP, the insertion patterns IL, the metal patterns MP, and the gate insulating patterns GI that are interposed between the semiconductor patterns SP and the gate electrodes GE. The semiconductor pattern SP included in the FETs may include the first impurity regions IR1, the second impurity regions IR2, and the channel regions CH. As an example, an FET may have the first conductive lines CL1 that function as bitlines, and the second conductive lines CL2 that function as source lines. Alternatively, the first conductive lines CL1 may function as source lines, and the second conductive lines CL2 may function as bitlines.

The semiconductor patterns SP may have a channel-all-around structure that surrounds the gate electrodes GE. Thus, during operation of the semiconductor memory device according to embodiments, when an electric field is applied from the gate electrodes GE to the channel regions CH, the electric field can be prevented from concentrating on the gate insulating patterns GI interposed between the gate electrodes GE and the channel regions CH.

The second insulating patterns 120 may be disposed between vertically adjacent first conductive lines CL1 and between vertically adjacent second conductive lines CL2. The second insulating patterns 120 and the first conductive lines CL1 may be alternately stacked in the vertical direction D3. The second insulating patterns 120 and the second conductive lines CL2 may also be alternately stacked in the vertical direction D3.

The second insulating patterns 120 may surround the sides of the corresponding gate electrodes GE. The second insulating patterns 120 may extend between vertically adjacent semiconductor patterns SP, vertically adjacent gate insulating patterns GI, and vertically adjacent metal patterns MP.

The first insulating patterns 110 may be formed at the same level as the first conductive lines CL1 and the second conductive lines CL2. The first insulating patterns 110 may be disposed between adjacent semiconductor patterns SP in the first horizontal direction D1. The first insulating patterns 110 may fill the spaces between the first conductive lines CL1 and the second conductive lines CL2 and adjacent second insulating patterns 120 in the vertical direction D3. The first insulating patterns 110 may partially surround the sides of the corresponding gate electrodes GE.

The first insulating patterns 110 and the second insulating patterns 120 may each include, for example, at least one selected from a silicon oxide film, a silicon nitride film, a silicon oxynitride film, a carbon (Ca)-containing silicon oxide film, a Ca-containing silicon nitride film, and a Ca-containing silicon oxynitride film.

In embodiments, the insertion patterns IL may also be disposed between the second insulating patterns 120 and the gate electrodes GE. The insertion patterns IL may extend between the second insulating patterns 120 and the gate electrodes GE. The insertion patterns IL may extend along the sidewalls and the bottom surfaces of the gate electrodes GE. The insertion patterns IL may extend between the second insulating patterns 120 and the gate electrodes GE. The insertion patterns IL may also be disposed between the first insulating patters 110 and the gate electrodes GE. In embodiments, semiconductor patterns SP, gate insulating patterns GI, and metal patterns MP may also be disposed between the first insulating patters 110 and the gate electrodes GE.

In some embodiments, the stacked structures SS may further include first dummy semiconductor patterns DSP1, second dummy semiconductor patterns DSP2, and intermediate insulating films 112. Alternatively, the first dummy semiconductor patterns DSP1, the second dummy semiconductor patterns DSP2, and the intermediate insulating films 112 may be omitted.

The intermediate insulating films 112 may be disposed on the second insulating patterns 120 in the vertical direction D3. The intermediate insulating films 112 may be disposed at the uppermost level of the stacked structures SS. The intermediate insulating films 112 may surround the sides of the corresponding gate electrodes GE.

The first dummy semiconductor patterns DSP1 may be disposed between the gate electrodes GE and the intermediate insulating films 112. The first dummy semiconductor patterns DSP1 may be spaced apart from the semiconductor patterns SP in the vertical direction D3. In embodiments, the first dummy semiconductor patterns DSP1 may be placed at a same level as that of the semiconductor patterns SP in the vertical direction (e.g., the first dummy semiconductor patterns DSP1 and the semiconductor patterns SP may be at a same or approximately same distance from the gate electrodes GE in a horizontal plane made by first horizontal direction D1 and second horizontal direction D2). In a plan view, the first dummy semiconductor patterns DSP1 may have an annular shape. The insertion patterns IL, the metal patterns MP, and the gate insulating patterns GI may be disposed between the gate electrodes GE and the first dummy semiconductor patterns DSP1.

The second dummy semiconductor patterns DSP2 may be disposed on the bottom surfaces of the gate electrodes GE. At least portions of the second dummy semiconductor patterns DSP2 may be disposed in the etch stop film 104. The insertion patterns IL, the metal patterns MP, and the gate insulating patterns GI may be disposed between the gate electrodes GE and the second dummy semiconductor patterns DSP2.

The first dummy semiconductor patterns DSP1 and the second dummy semiconductor patterns DSP2 may include the same material as the semiconductor patterns SP. The first dummy semiconductor patterns DSP1 and the second dummy semiconductor patterns DSP2 may not include the first impurity regions IR1 and the second impurity regions IR2.

The separation structures 130 may be disposed on the etch stop film 104. The separation structures 130 may be disposed on both sides of the stacked structures SS in the second horizontal direction D2. The separation structures 130 may extend in the first horizontal direction D1 along both sides of the stacked structures SS in the second horizontal direction D2. The separation structures 130 may be disposed between adjacent stacked structures SS in the second horizontal direction D2. The separation structures 130 may include, for example, silicon oxide, silicon nitride, and/or silicon oxynitride.

The upper insulating film 140 may be disposed on the stacked structures SS and the separation structures 130. The upper insulating film 140 may include, for example, silicon oxide, silicon nitride, and/or silicon oxynitride.

The wires 150 may be disposed in the upper insulating film 140. The contacts 142 may be etched into upper insulating film 140. The wires 150 may be electrically connected to the gate electrodes GE via the contacts 142. The contacts 142 and the wires 150 may each include a conductive material, such as a metal.

Referring to FIGS. 5 through 8, the gate insulating patterns GI and the semiconductor patterns SP may extend along the sides of the metal patterns MP. As an example, gate insulating patterns GI and the semiconductor patterns SP may extend along the a same side of the metal patterns MP in the first horizontal direction D1. The gate insulating patterns GI and the semiconductor patterns SP may overlap with the metal patterns MP in a direction parallel to the upper surface 100U of the substrate 100.

Referring to FIG. 5, in some embodiments, a length W2 of the gate insulating patterns GI in the vertical direction D3 may be greater than a length W1 of the metal patterns MP in the vertical direction D3. The length W2 of the gate insulating patters may be smaller than a length W3 of the semiconductor patterns SP in the vertical direction D3. The upper surfaces of the metal patterns MP, the gate insulating patterns GI, and the semiconductor patterns SP may be positioned at different levels. The bottom surfaces of the metal patterns MP, the gate insulating patterns GI, and the semiconductor patterns SP may also be positioned at different levels. The upper surfaces and bottom surfaces of the metal patterns MP, the gate insulating patterns GI, and the semiconductor patterns SP may be flat.

Referring to FIGS. 6 and 7, in embodiments, the upper surface and bottom surface of at least one of the metal patterns MP, the gate insulating patterns GI, or the semiconductor patterns SP may be curved. For example, referring to FIG. 6, the length W1 of the metal patterns MP in the vertical direction D3 may decrease closer to the gate electrodes GE. The upper surfaces of the metal patterns MP may be convex toward the bottom surfaces of the metal patterns MP, and the bottom surfaces of the metal patterns MP may be convex toward the upper surfaces of the metal patterns MP. As another example, referring to FIG. 7, the length W1 of the metal patterns MP in the vertical direction D3 and the length W2 of the gate insulating patterns GI in the vertical direction D3 may decrease closer to the gate electrodes GE. The upper surfaces of the metal patterns MP may be convex toward the bottom surfaces of the metal patterns MP, and the bottom surfaces of the metal patterns MP may be convex toward the upper surfaces of the metal patterns MP. The upper surfaces of the gate insulating patterns GI may be convex toward the bottom surfaces of the gate insulating patterns GI, and the bottom surfaces of the gate insulating patterns GI may be convex toward the upper surfaces of the gate insulating patterns GI.

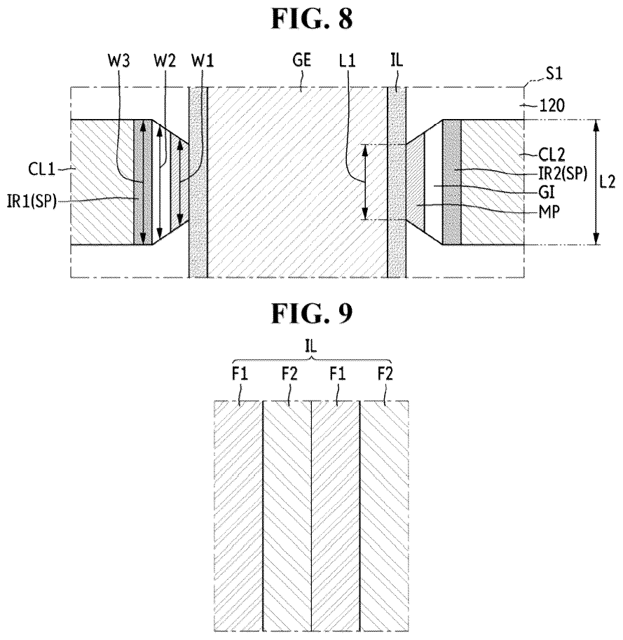

Referring to FIG. 8, in embodiments, the length W1 of the metal patterns MP in the vertical direction D3 and the length W2 of the gate insulating patterns GI in the vertical direction D3 may decrease closer to the gate electrodes GE. The upper surfaces and bottom surfaces of the metal patterns MP and the upper surfaces and bottom surfaces of the gate insulating patterns GI may have a slope.

Referring to FIGS. 5 through 8, the capacitance of the insertion patterns IL is proportional to the area of the insertion patterns IL in contact with the metal patterns MP. The length L1 is the length of the metal patterns MP in contact with insertion patterns IL in the vertical direction D3 but the disclosure is not limited thereto. The area of the insertion patterns IL in contact with the metal patterns MP is proportional to the length L1 of the insertion patterns IL in contact with the metal patterns MP. The capacitance of the gate insulating patterns GI is proportional to the average area of the gate insulating patterns GI in contact with the metal patterns MP and the semiconductor patterns SP. The length L2 is the length of the gate insulating patterns GI in contact with semiconductor patterns SP in the vertical direction D3. In embodiments, length L2 may be the length of the gate insulating patterns GI in contact with the metal patterns MP when length W1 and length W2 are same. While the disclosures with respect to FIGS. 5-8 discuss length as measured in the vertical direction D3. However, it is understood that this is exemplary. The length may be measured in terms of circumference where applicable. The average area of the gate insulating patterns GI in contact with the metal patterns MP and the semiconductor patterns SP is proportional to the average of the length L1 of the gate insulating patterns GI in contact with the metal patterns MP and the length L2 of the gate insulating patterns GI in contact with the semiconductor patterns SP.

The length L1 of the insertion patterns IL in contact with the metal patterns MP is smaller than the length L2 of the gate insulating patterns GI in contact with the semiconductor patterns SP. The area of the insertion patterns IL in contact with the metal patterns MP is smaller than the area of the gate insulating patterns GI in contact with the semiconductor patterns SP. Therefore, the capacitance of the insertion patterns IL is smaller than the capacitance of the gate insulating patterns GI. As a result, an advantage of the disclosed stacked structure SS is that the electric field applied to the gate insulating patterns GI is reduced, preventing the degradation of the gate insulating patterns GI. Also, the electric field applied to the insertion patterns IL is increased, improving dipole switching efficiency and enhancing the memory window.

FIG. 9 is a diagram for explaining an insertion pattern IL of some embodiments.

Referring to FIG. 9, in some embodiments, the insertion pattern IL may include different first films F1 (also referred to as IL1 in FIG. 9) and second films F2 (also referred to as IL2 in FIG. 9). The insertion pattern IL may include first films F1 and second films F2 that are alternately stacked.

In some embodiments, the insertion pattern IL may include a laminate structure in which two or more types of ferroelectric layers are stacked. The first films F1 and the second films F2 may each include a ferroelectric material. The first films F1 and the second films F2 may each be selected from the ferroelectric materials mentioned in this disclosure. That is, the insertion pattern IL may include different first ferroelectric patterns and second ferroelectric patterns.

In some embodiments, the insertion pattern IL may include a laminate structure in which ferroelectric layers and dielectric layers are stacked. The first films F1 may include a ferroelectric material, and the second films F2 may include a dielectric material. That is, the insertion pattern IL may include ferroelectric patterns and dielectric patterns. The dielectric material may include a silicon oxide film, a high-k dielectric film, or a combination thereof. The high-k dielectric film may include a metal oxide or a metal oxynitride with a greater dielectric constant than silicon oxide.

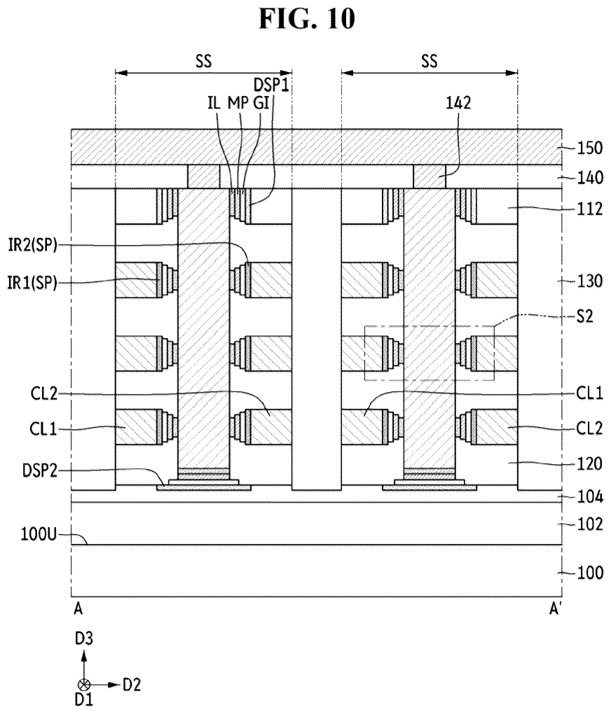

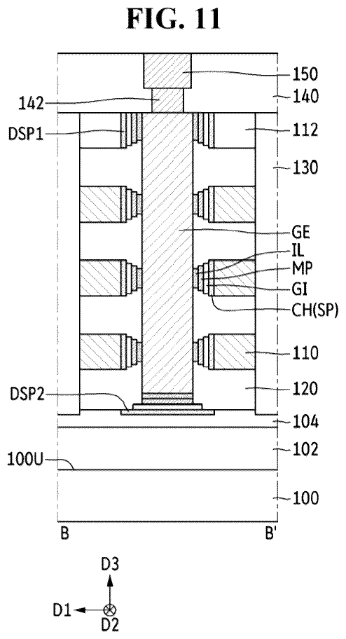

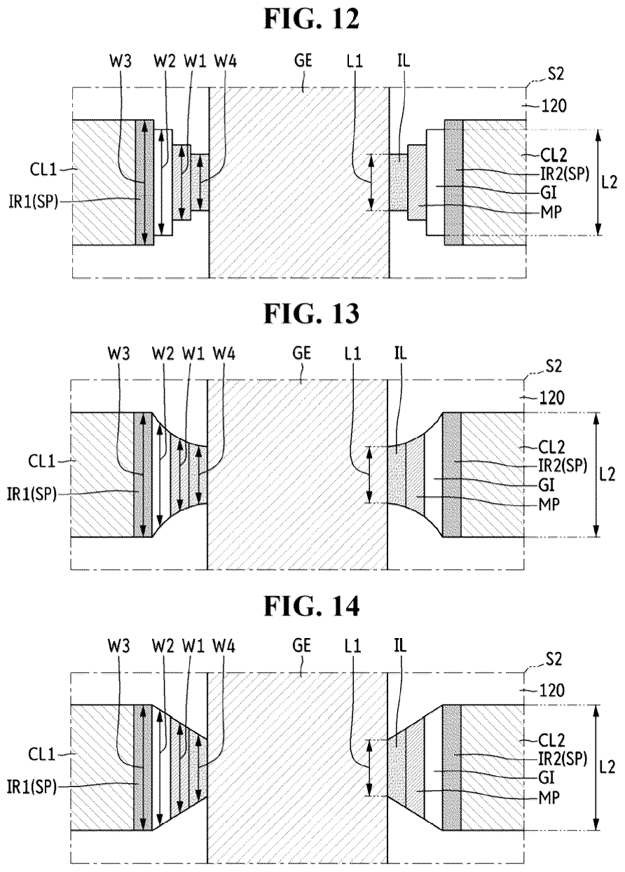

FIGS. 10 and 11 are diagrams for explaining a semiconductor memory device according to some embodiments. FIGS. 12 through 14 are enlarged diagrams of area S2 of FIG. 10. Specifically, FIG. 10 is a cross-sectional view taken along line A-A′ of FIG. 2, and FIG. 11 is a cross-sectional view taken along line B-B′ of FIG. 2. For convenience of explanation, the differences from what has been described above with reference to FIGS. 1 through 9 will be focused on.

Referring to FIGS. 10 and 11, in the semiconductor memory device according to some embodiments, insertion patterns IL may expose the side surfaces of gate electrodes GE. Second insulating patterns 120 may extend between adjacent insertion patterns IL in the vertical direction D3. That is, the insertion patterns IL may not be disposed between the second insulating patterns 120 and the gate electrodes GE.

Referring to FIG. 12, in some embodiments, a length W4 of the insertion patterns IL in the vertical direction D3 may be smaller than a length W1 of metal patterns MP in the vertical direction D3, the length W2 of the gate insulating patterns GI in the vertical direction D3, and/or W3 of the semiconductor patterns SP in the vertical direction D3. The upper surfaces of the insertion patterns IL may be positioned at a different level from the upper surfaces of the metal patterns MP, gate insulating patterns GI, and semiconductor patterns SP. The lower surfaces of the insertion patterns IL may also be positioned at a different level from the lower surfaces of the metal patterns MP, the gate insulating patterns GI, and the semiconductor patterns SP. The upper surfaces and lower surfaces of the insertion patterns IL may be flat.

Referring to FIG. 13, in some embodiments, the upper surface and lower surface of at least one of the insertion patterns IL, the metal patterns MP, the gate insulating patterns GI, or the semiconductor patterns SP may be curved. For example, the length W4 of the insertion patterns IL in the vertical direction D3 may decrease closer to the gate electrodes GE. The upper surfaces of the insertion patterns IL may be convex toward the lower surfaces of the insertion patterns IL, and the lower surfaces of the insertion patterns IL may be convex toward the upper surfaces of the insertion patterns IL.

Referring to FIG. 14, in some embodiments, the length W4 of the insertion patterns IL in the vertical direction D3 may decrease closer to the gate electrodes GE. The upper surfaces and lower surfaces of the insertion patterns IL may have a slope.

While the disclosures with respect to FIGS. 5-8 discuss length as measured in the vertical direction D3. However, it is understood that this is exemplary. The length may be measured in terms of circumference where applicable.

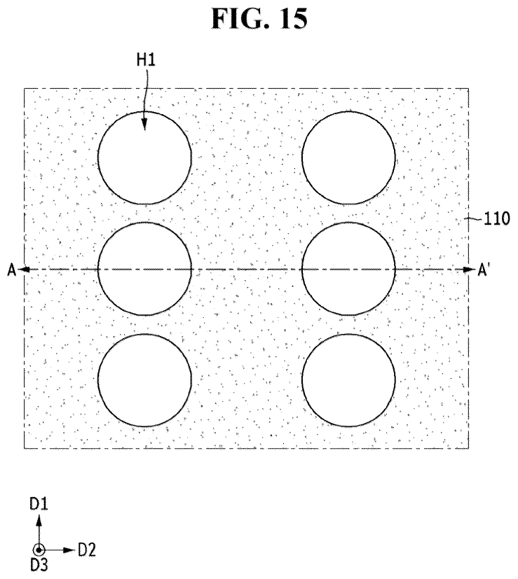

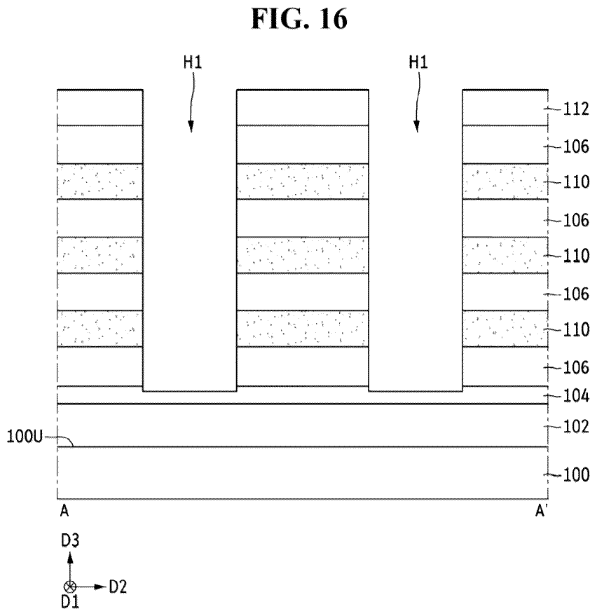

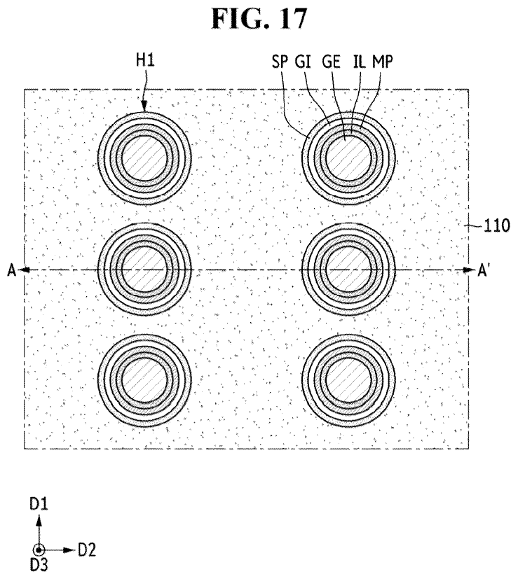

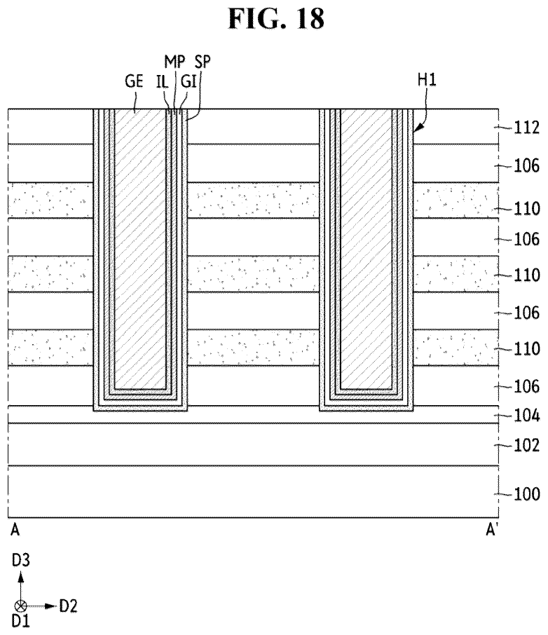

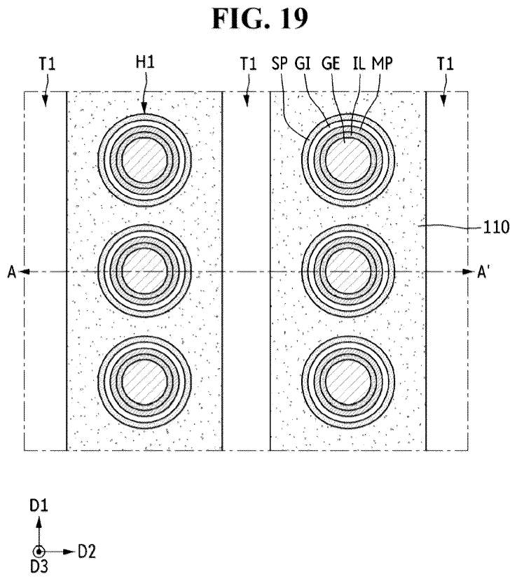

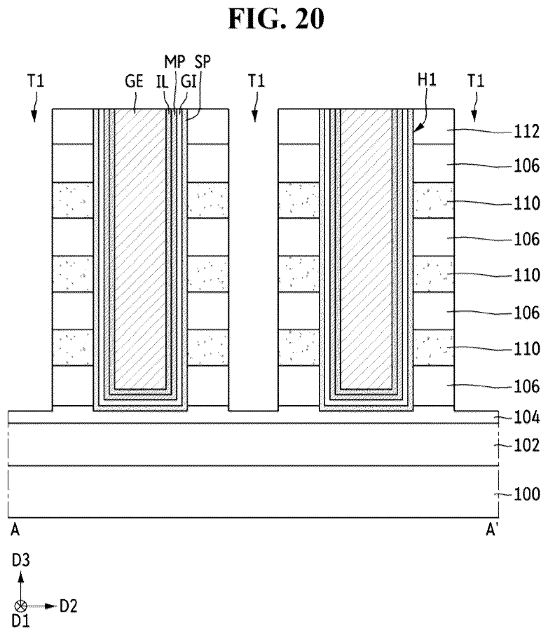

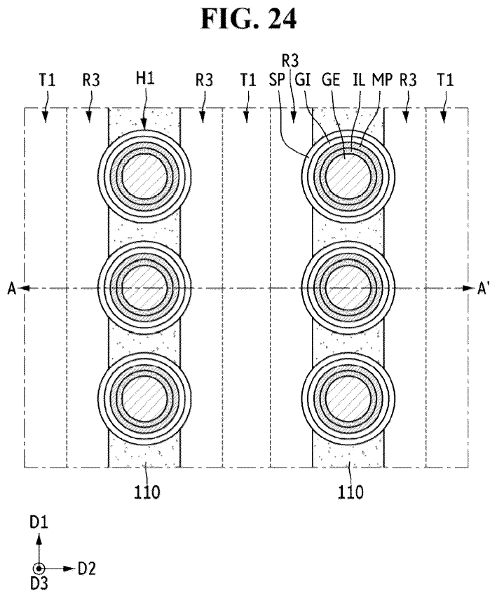

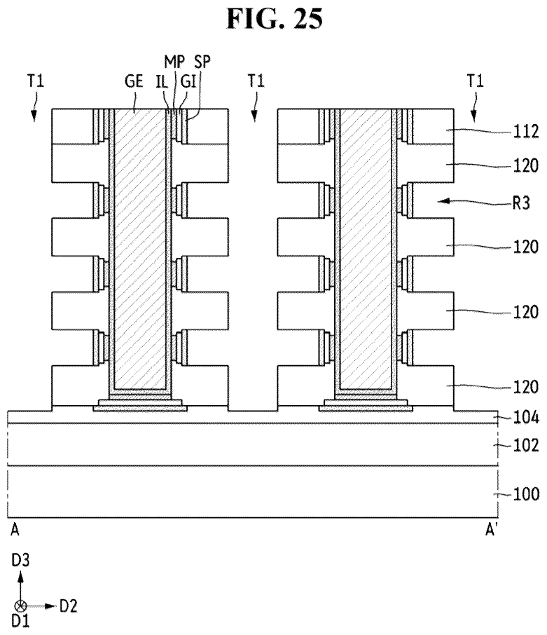

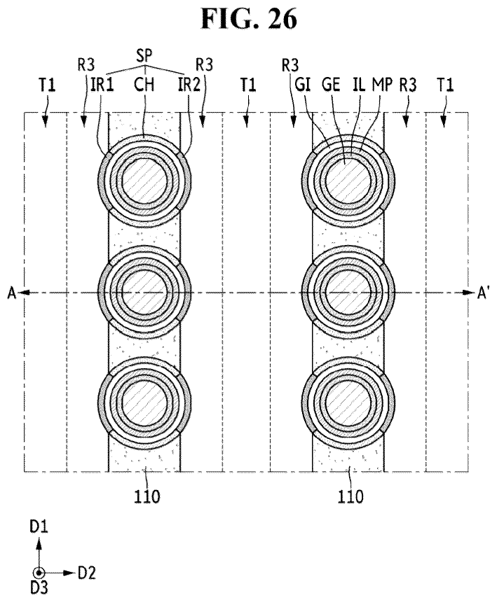

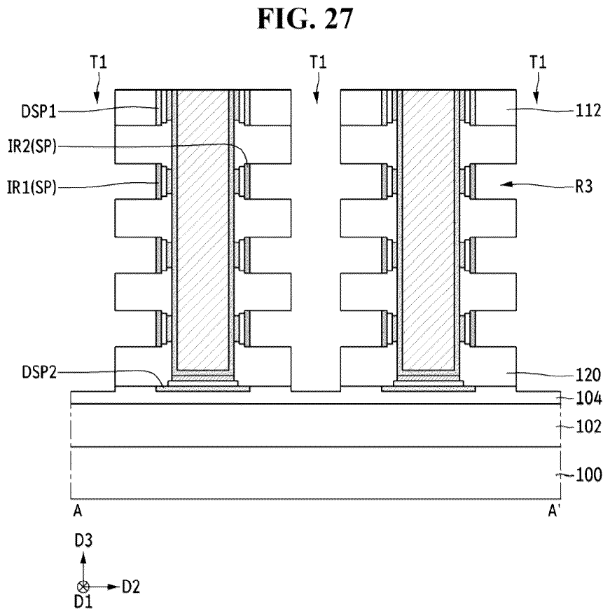

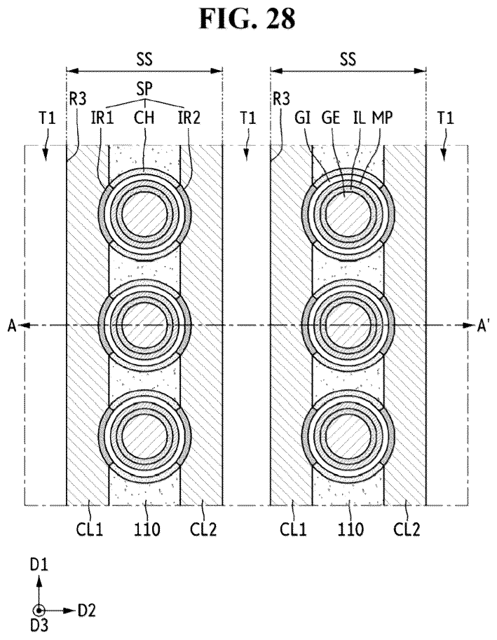

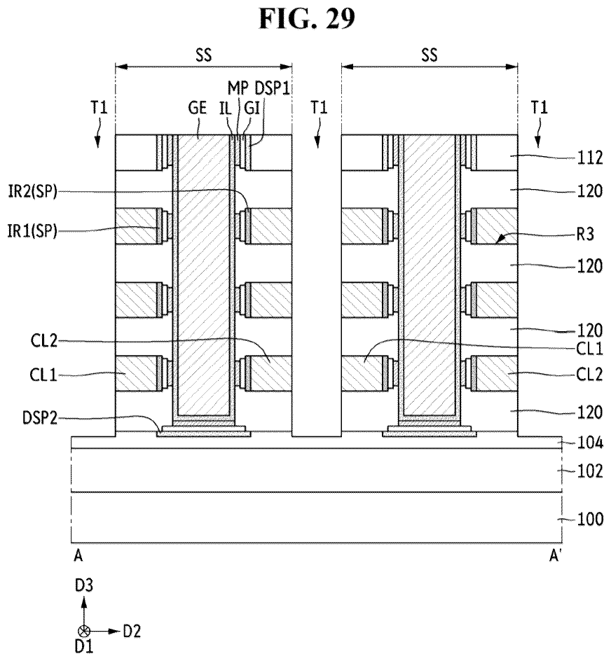

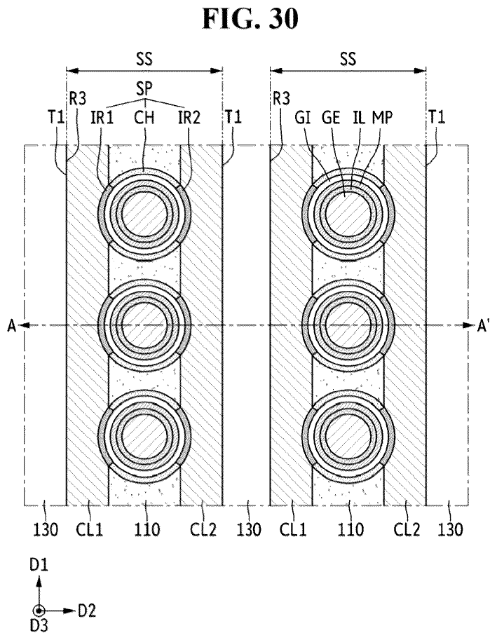

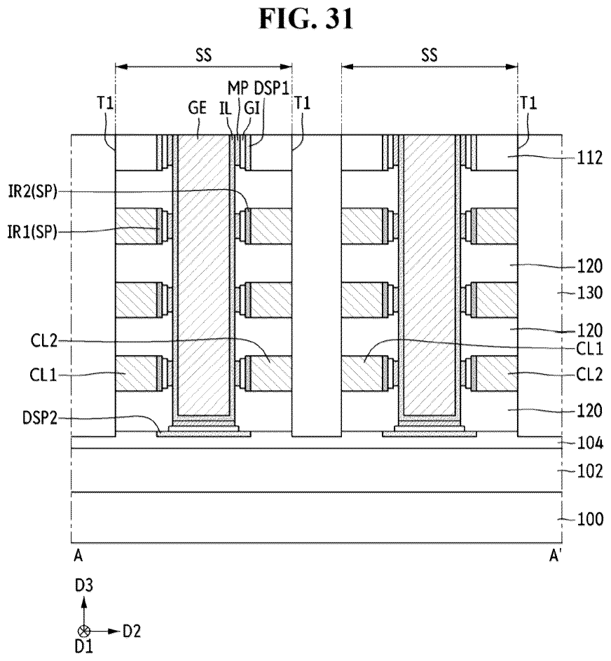

FIGS. 15 through 31 are diagrams illustrating a method or a process for manufacturing a semiconductor memory device according to some embodiments. Specifically, FIG. 16 is a cross-sectional view taken along line A-A′ of FIG. 15 and FIG. 18 is a cross-sectional view taken along line A-A′ of FIG. 17. FIGS. 20 through 23 are cross-sectional views taken along line A-A′ of FIG. 19. FIG. 25 is a cross-sectional view taken along line A-A′ of FIG. 24 and FIG. 27 is a cross-sectional view taken along line A-A′ of FIG. 26. FIG. 29 is a cross-sectional view taken along line A-A′ of FIG. 28, and FIG. 31 is a cross-sectional view taken along line A-A′ of FIG. 30.

FIGS. 15, 17, 19, 24, 26, 28, and 30 are top views of an uppermost first insulating pattern 110. For convenience of explanation, the differences from what has been explained above with reference to FIGS. 1 through 9 will be focused on.

Referring to FIGS. 15 and 16, a lower insulating film 102 and an etch stop film 104 may be sequentially formed on an upper surface 100U of a substrate 100.

Sacrificial patterns 106 and first insulating patterns 110 may be alternately stacked along the vertical direction D3 on the etch stop film 104. The lowermost sacrificial pattern 106 may be disposed between the etch stop film 104 and the lowermost first insulating pattern 110. The uppermost sacrificial pattern 106 may be disposed on the uppermost first insulating pattern 110. An intermediate insulating film 112 may be further formed on the uppermost sacrificial pattern 106.

The sacrificial patterns 106 may include a material with an etch selectivity with respect to the first insulating patterns 110. For example, the first insulating patterns 110 may include silicon oxide, and the sacrificial patterns 106 may include silicon nitride.

The intermediate insulating film 112 may include a material with an etch selectivity with respect to both the sacrificial patterns 106 and the first insulating patterns 110.

The sacrificial patterns 106 and the first insulating patterns 110 may each include an insulating material. The sacrificial patterns 106 may have an etch selectivity with respect to the first insulating patterns 110. The sacrificial patterns 106 and the first insulating patterns 110 may each include, for example, at least one selected from a silicon oxide film, a silicon nitride film, a silicon oxynitride film, a Ca-containing silicon oxide film, a Ca-containing silicon nitride film, and a Ca-containing silicon oxynitride film. For example, the first insulating patterns 110 may include a silicon oxide film, and the sacrificial patterns 106 may include a silicon nitride film.

Thereafter, first holes H1 penetrating the intermediate insulating film 112, the sacrificial patterns 106, and the first insulating patterns 110 may be formed as shown in FIGS. 17 and 18. The first holes H1 may expose the etch stop film 104. The bottom surfaces of the first holes H1 may be positioned between the upper and lower surfaces of the etch stop film 104. The first holes H1 may be spaced apart along the first and second horizontal directions D1 and D2.

Referring to FIGS. 17 and 18, semiconductor patterns SP, gate insulating patterns GI, metal patterns MP, insertion patterns IL, and gate electrodes GE may be formed in the first holes H1. The semiconductor patterns SP may extend along an inside edge of the first holes H1 with a stacking of the etch stop film 104, layers of sacrificial patterns 106 and first insulating patterns 110, and intermediate insulating film 112 extending along an outside edge of the first holes H1.

The semiconductor patterns SP may extend along the sidewalls and the bottom surfaces of the first holes H1. The gate insulating patterns GI may extend along the semiconductor patterns SP. The metal patterns MP may extend along the gate insulating patterns GI. The insertion patterns IL may extend along the metal patterns MP. The gate electrodes GE may fill the first holes H1 on the insertion patterns IL.

Referring to FIGS. 19 and 20, first trenches T1 penetrating the intermediate insulating film 112, the sacrificial patterns 106, and the first insulating patterns 110 may be formed. The first trenches T1 may expose the etch stop film 104. The bottom surfaces of the first trenches T1 may be positioned between the upper and lower surfaces of the etch stop film 104. The first trenches T1 may extend in the first horizontal direction D1. The first trenches T1 may be spaced apart in the second horizontal direction D2. The first trenches T1 may have a same depth as the first holes H1 in the vertical direction D3.

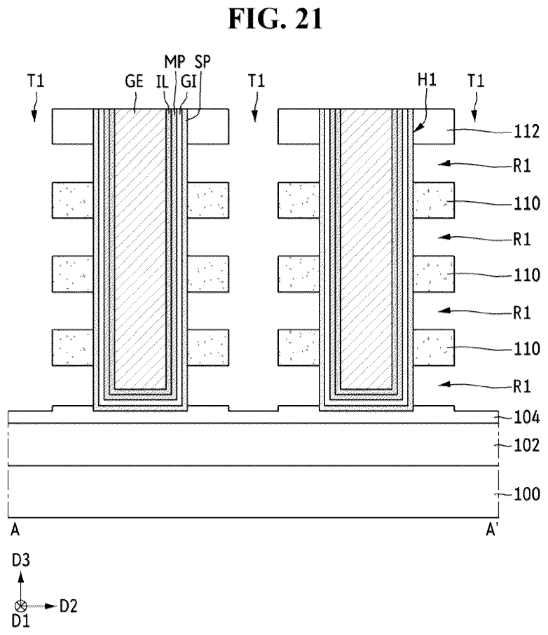

Referring to FIGS. 20 and 21, the sacrificial patterns 106 exposed by the first trenches T1 may be removed to form first recess regions R1. The first recess regions R1 may expose the side surfaces of the semiconductor patterns SP. The first recess regions R1 may be spaced apart in the vertical direction D3 and may be interposed between the first insulating patterns 110. The first recess regions R1 may be formed to surround the first holes H1 in a plan view.

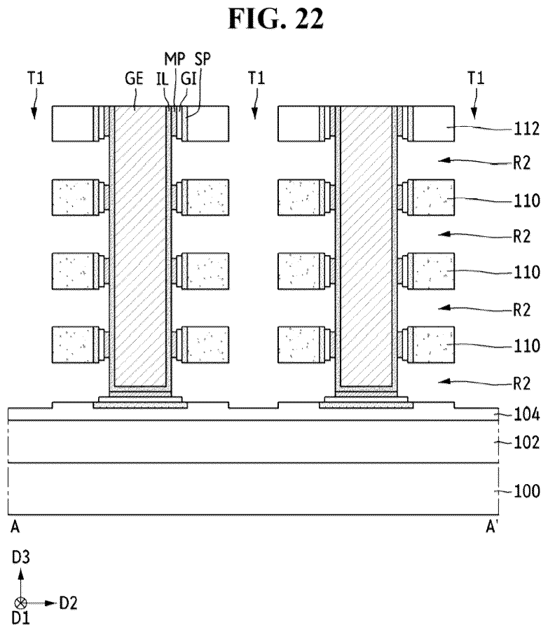

Referring to FIGS. 21 and 22, the semiconductor patterns SP, the gate insulating patterns GI, and the metal patterns MP may be removed through the first recess regions R1, thereby forming second recess regions R2. The second recess regions R2 may extend first recess regions R1 in the second horizontal direction D2. In some embodiments, the second recess regions R2 may expose the side surfaces of the insertion patterns IL. In embodiments, the second recess regions R2 may expose the side surfaces of gate electrodes GE. The various shapes of the semiconductor patterns SP, the gate insulating patterns GI, and the metal patterns MP in FIGS. 5 through 8 may result from the process of forming the second recess regions R2.

The second recess regions R2 may be spaced apart in the vertical direction D3. Semiconductor patterns SP, gate insulating patterns GI, and metal patterns MP that are spaced apart in the vertical direction D3, surrounding a single gate electrode GE, may be separated by the second recess regions R2. Semiconductor patterns SP, gate insulating patterns GI, and metal patterns MP surrounding a single gate electrode GE may be spaced apart in the vertical direction D3. The semiconductor patterns SP may be separated by the second recess regions R2, forming first dummy semiconductor patterns DSP1 in the intermediate insulating film 112 and second dummy semiconductor patterns DSP2 on the bottom surfaces of the gate electrodes GE.

In some embodiments, the insertion patterns IL may be further removed through the first recess regions R1, thereby forming the second recess regions R2. In this case, the various shapes of the gate insulating patterns GI, the metal patterns MP, and the insertion patterns IL in FIGS. 12 through 14 may result from the process of forming the second recess regions R2.

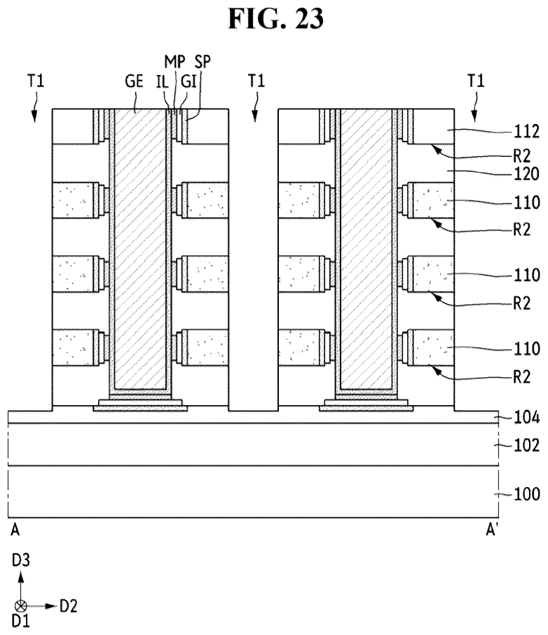

Referring to FIG. 23, second insulating patterns 120 that fill the second recess regions R2 may be formed. The first trenches T1 may expose the side surfaces of the intermediate insulating film 112, the first insulating patterns 110, and the second insulating patterns 120.

Referring to FIGS. 2 and 25, portions of the first insulating patterns 110 exposed by the first trenches T1 may be removed, thereby forming third recess regions R3. The third recess regions R3 may extend in the first horizontal direction D1. The first insulating patterns 110 between adjacent semiconductor patterns SP in the first horizontal direction D1 may remain. The third recess regions R3 may be spaced apart in the second horizontal direction D2 with the first insulating patterns 110 in between. The third recess regions R3 may expose the side surfaces of the semiconductor patterns SP and the first insulating patterns 110.

Referring to FIGS. 26 and 27, first impurity regions IR1 and second impurity regions IR2 may be formed in portions of the semiconductor patterns SP exposed through the third recess regions R3. The first impurity regions IR1 may be formed in portions of the semiconductor patterns SP exposed through the third recess regions R3 on first sides of the semiconductor patterns SP, and the second impurity regions IR2 may be formed in portions of the semiconductor patterns SP exposed through the third recess regions R3 on second sides of the semiconductor patterns SP. The first sides and the second sides may be opposite to each other in the second horizontal direction D2. Accordingly, semiconductor patterns SP including the first impurity regions IR1, channel regions CH, and the second impurity regions IR2 may be formed.

Since the first dummy semiconductor patterns DSP1 are covered by the intermediate insulating film 112, the first impurity regions IR1 and the second impurity regions IR2 may not be formed in the first dummy semiconductor patterns DSP1. Since the second dummy semiconductor patterns DSP2 are covered by the second insulating patterns 120, the first impurity regions IR1 and the second impurity regions IR2 may not be formed in the second dummy semiconductor patterns DSP2.

Forming the first impurity regions IR1 and the second impurity regions IR2 may involve doping impurities into the side surfaces of the semiconductor patterns SP exposed by the third recess regions R3.

Referring to FIGS. 28 and 29, first conductive lines CL1 filling the third recess regions R3 may be formed on the first impurity regions IR1. Second conductive lines CL2 filling the third recess regions R3 may be formed on the second impurity regions IR2. The first insulating patterns 110 may be interposed between pairs of adjacent first and second conductive lines CL1 and CL2 in the second horizontal direction D2. Accordingly, stacked structures SS including the first conductive lines CL1, the second conductive lines CL2, the gate electrodes GE, the insertion patterns IL, the metal patterns MP, the gate insulating patterns GI, the semiconductor patterns SP, the first insulating patterns 110, and the second insulating patterns 120 may be formed.

Referring to FIGS. 30 and 31, separation structures 130 filling the first trenches T1 may be formed. The separation structures 130 may be formed between the stacked structures SS.

Referring now to FIGS. 2 through 4, an upper insulating film 140, contacts 142, and wires 150 may be formed on the stacked structures SS and the separation structures 130.

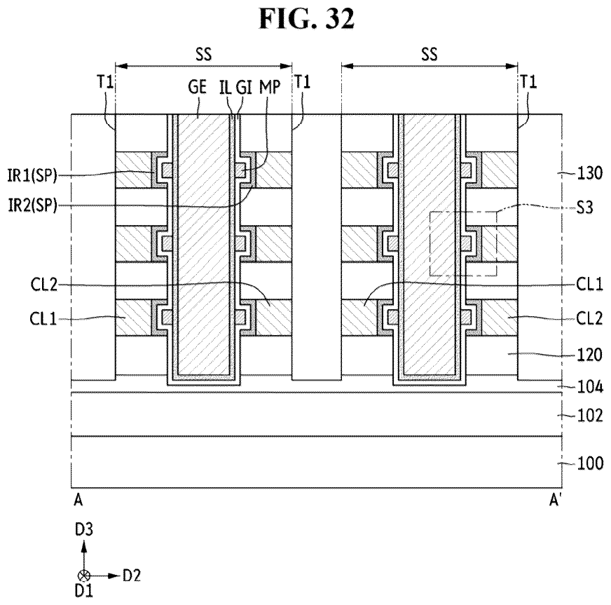

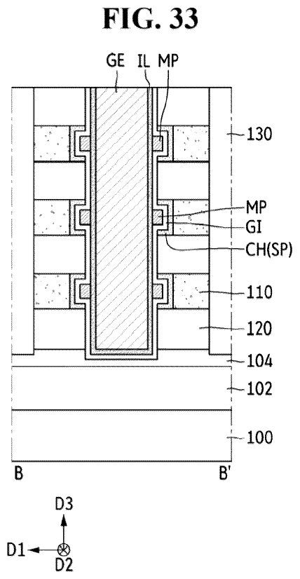

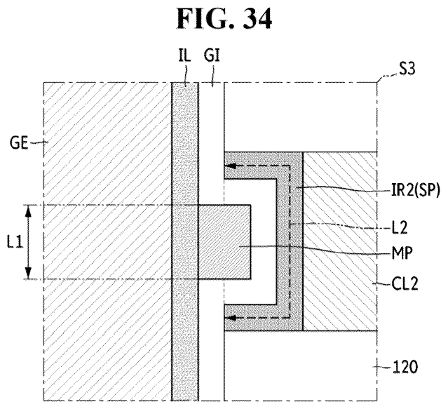

FIGS. 32 through 34 are diagrams for explaining a semiconductor memory device according to some embodiments. Specifically, FIGS. 32 and 33 are cross-sectional views taken along lines A-A′ and B-B′ of FIG. 2, but FIGS. 32 and 33 omit the upper insulating film 140, contacts 142, and wires 150 of FIG. 2. FIG. 34 is an enlarged cross-sectional view of area S3 of FIG. 32. For convenience, the differences from what has been explained with reference to FIGS. 1 through 9 will be focused on.

Referring to FIGS. 32 through 34, in the semiconductor memory device according to some embodiments, gate insulating patterns GI may extend along the upper surfaces, lower surfaces, and side surfaces of metal patterns MP. The gate insulating patterns GI may be disposed between second insulating patterns 120 and insertion patterns IL. The gate insulating patterns GI may extend between the second insulating patterns 120 and the insertion patterns IL. The gate insulating patterns GI may extend along the insertion patterns IL.

Semiconductor patterns SP may be disposed between the gate insulating patterns GI and first conductive line CL1, and between the gate insulating patterns GI and second conductive lines CL2. The semiconductor patterns SP may extend along the gate insulating patterns GI. The semiconductor patterns SP may have a hollow cylindrical shape. The semiconductor patterns SP may have a U-shape rotated 90 degrees toward gate electrodes GE.

The metal patterns MP may protrude from the insertion patterns IL, and the gate insulating patterns GI and the semiconductor patterns SP may extend along the metal patterns MP. Thus, a length L1 of the insertion patterns IL in contact with the metal patterns MP is smaller than a length L2 of the gate insulating patterns GI in contact with the semiconductor patterns SP. The length L2 may be a combination of the lengths of every side of the fate insulating patters in contact with the semiconductor patters SP. Accordingly, a semiconductor memory device is provided in which the deterioration of the gate insulating patterns GI is prevented, and the memory window is improved.

First insulating patterns 110 may include a material different from the second insulating patterns 120. The first insulating patterns 110 may have an etch selectivity with respect to the second insulating patterns 120. For example, the first insulating patterns 110 may include silicon oxide, and the second insulating patterns 120 may include silicon nitride.

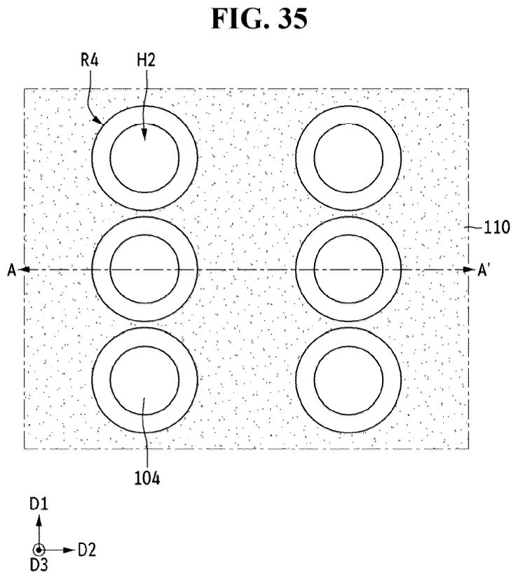

FIGS. 35 through 44 are diagrams illustrating a method or process of manufacturing a semiconductor memory device according to some embodiments.

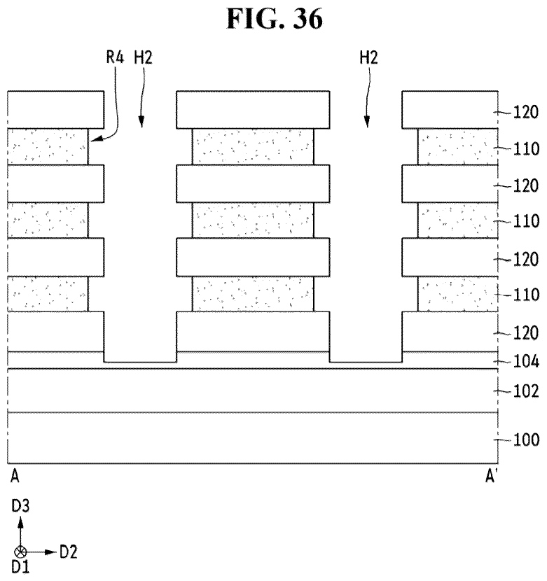

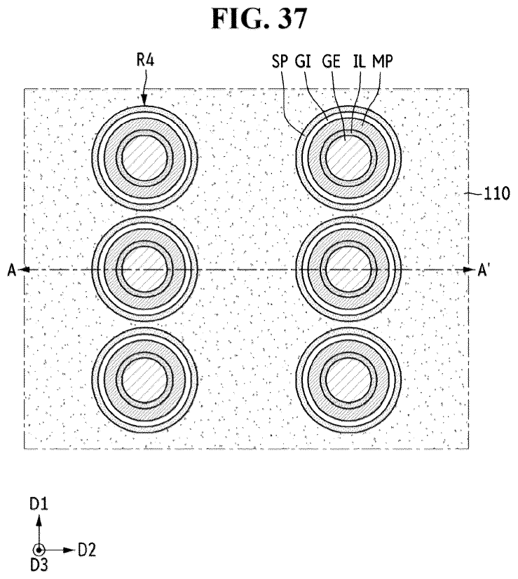

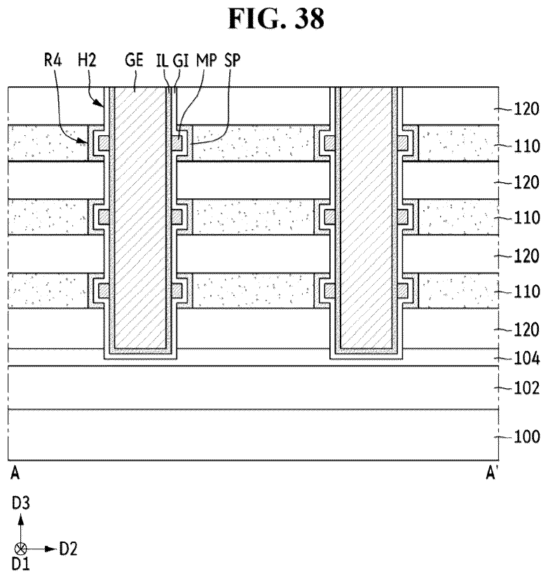

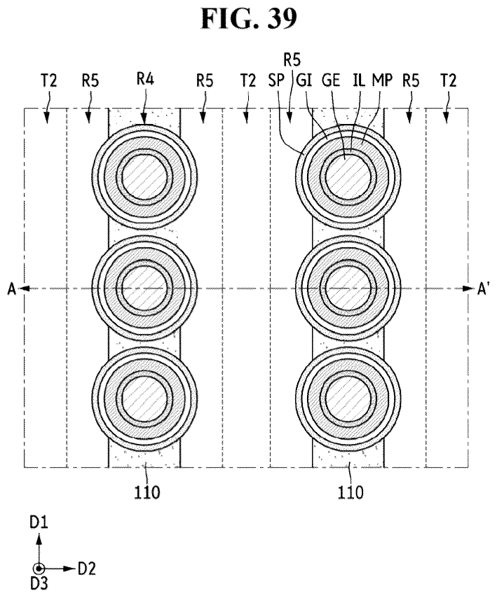

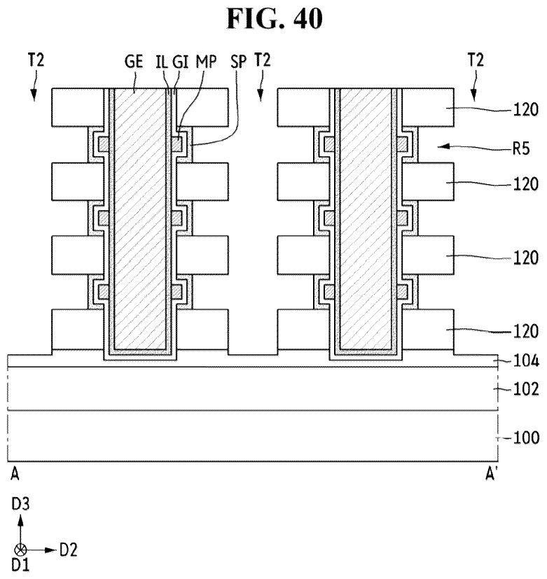

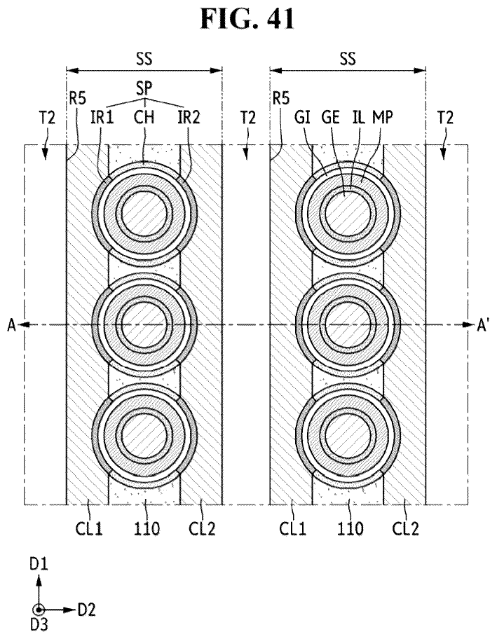

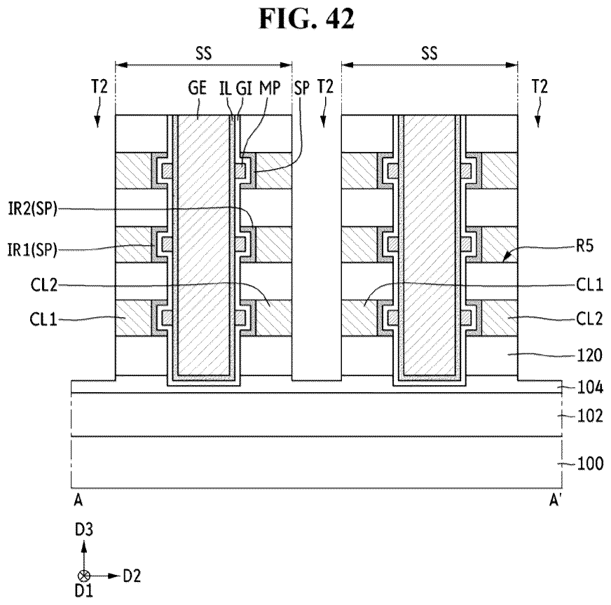

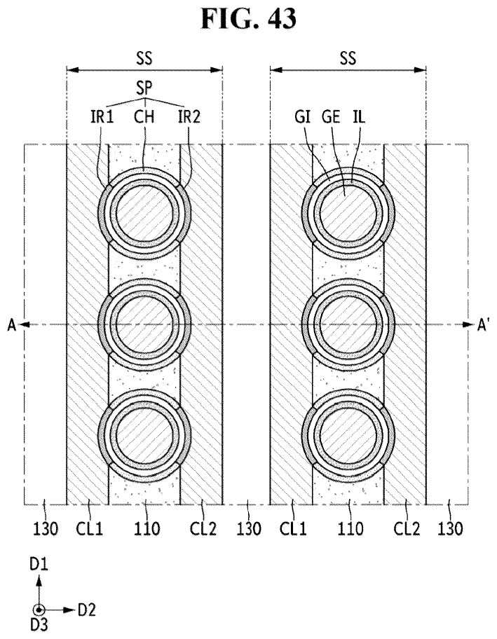

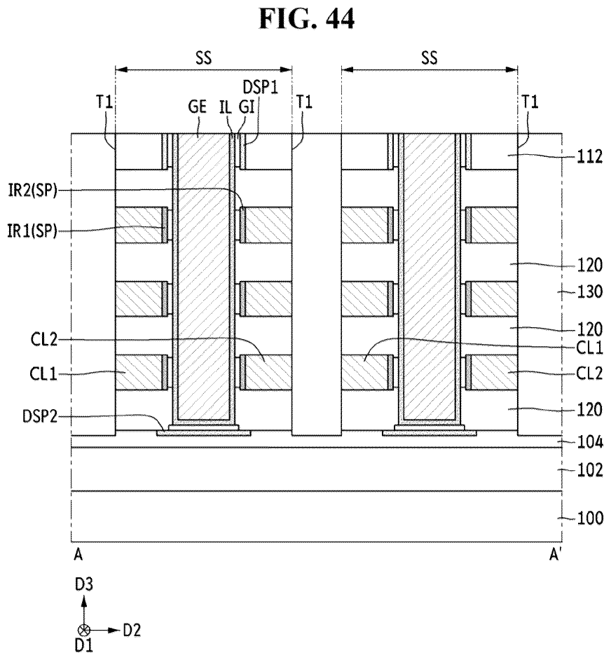

FIG. 36 is a cross-sectional view taken along line A-A′ of FIG. 35. FIG. 38 is a cross-sectional view taken along line A-A′ of FIG. 37. FIG. 40 is a cross-sectional view taken along line A-A′ of FIG. 39. FIG. 42 is a cross-sectional view taken along line A-A′ of FIG. 41. FIG. 44 is a cross-sectional view taken along line A-A′ of FIG. 43. FIGS. 35, 37, 39, 41, and 43 are top views of an uppermost first insulating pattern 110. For convenience, the differences from what has been explained with reference to FIGS. 1 through 34 will be focused on.

Referring to FIGS. 35 and 36, a lower insulating film 102 and an etch stop film 104 may be sequentially formed on an upper surface 100U of a substrate 100.

First insulating patterns 110 and second insulating patterns 120 may be alternately stacked in the vertical direction D3 on the etch stop film 104. The lowermost second insulating pattern 120 may be disposed between the etch stop film 104 and the lowermost first insulating pattern 110. The uppermost second insulating pattern 120 may be disposed on the uppermost first insulating pattern 110.

The first insulating patterns 110 and the second insulating patterns 120 may each include, for example, at least one selected from a silicon oxide film, a silicon nitride film, a silicon oxynitride film, a Ca-containing silicon oxide film, a Ca-containing silicon nitride film, and a Ca-containing silicon oxynitride film. The first insulating patterns 110 may have an etch selectivity with respect to the second insulating patterns 120.

Thereafter, second holes H2 penetrating the first insulating patterns 110 and the second insulating patterns 120 may be formed. The second holes H2 may expose the etch stop film 104. The second holes H2 may be spaced apart in the first and second horizontal directions D1 and D2.

Thereafter, the first insulating patterns 110 exposed by the second holes H2 may be partially etched, thereby forming fourth recess regions R4. The fourth recess regions R4 may be formed between adjacent second insulating patterns 120 in the vertical direction D3.

Referring to FIGS. 37 and 38, semiconductor patterns SP may be formed in the fourth recess regions R4. The semiconductor patterns SP may extend along the fourth recess regions R4. The semiconductor patterns SP may extend along a side of the first insulating patterns 110 in the first horizontal direction D1 and extend along edges of second insulating patterns 120 that protrude beyond the first insulating patterns 110 in a second horizontal direction D2.

Thereafter, gate insulating patterns GI may be formed along the semiconductor patterns SP and the second holes H2. The gate insulating patterns GI may extend along the side surfaces of the second insulating patterns 120 exposed by the second holes H2 and along the upper surface of the etch stop film 104. The gate insulating patterns may be disposed on the sides of the semiconductor patterns SP that are not disposed on the first insulating patterns 110 and second insulating patterns 120.

Thereafter, metal patterns MP may be formed on the gate insulating patterns GI formed along the semiconductor patterns SP. The metal patterns MP may fill the fourth recess regions R4. The metal patterns MP may fill the spaces between the gate insulating patterns GI spaced apart in the vertical direction D3. The side surfaces of the gate insulating patterns GI and the side surfaces of the metal patterns MP may be substantially coplanar.

Thereafter, insertion patterns IL may be formed along the metal patterns MP and the gate insulating patterns GI. The insertion patterns IL may have a hollow cylindrical shape. The gate electrodes GE may fill the second holes H2 on the insertion patterns IL. The gate electrodes GE may fill the interior of the insertion patterns IL.

Referring to FIGS. 39 and 40, second trenches T2 penetrating the first insulating patterns 110 and the second insulating patterns 120 may be formed. The second trenches T2 may expose the etch stop film 104. The bottom surfaces of the second trenches T2 may be positioned between the upper and lower surfaces of the etch stop film 104.

The second trenches T2 may extend in the first horizontal direction D1. The second trenches T2 may be spaced apart in the second horizontal direction D2. The gate electrodes GE spaced apart in the first horizontal direction D1 may be positioned between the second trenches T2 spaced apart in the second horizontal direction D2.

Thereafter, the first insulating patterns 110 exposed by the second trenches T2 may be partially etched, thereby forming fifth recess regions R5. The fifth recess regions R5 may be formed between the adjacent second insulating patterns 120 in the vertical direction D3. The second insulating patterns 120 may include a material with etch selectivity with respect to the first insulating patterns 110.

Referring to FIGS. 41 and 42, first impurity regions IR1 and second impurity regions IR2 may be formed in portions of the semiconductor patterns SP exposed by the fifth recess regions R5. The first impurity regions IR1 may be formed in portions of the semiconductor patterns SP exposed through the third recess regions R3 on first sides of the semiconductor patterns SP, and the second impurity regions IR2 may be formed in portions of the semiconductor patterns SP exposed through the fifth recess regions R5 on second sides of the semiconductor patterns SP. The first sides and the second sides may be opposite to each other in the second horizontal direction D2. Accordingly, semiconductor patterns SP including the first impurity regions IR1, channel regions CH, and the second impurity regions IR2 may be formed.

Forming the first impurity regions IR1 and the second impurity regions IR2 may include doping impurities into the side surfaces of the semiconductor patterns SP exposed by the fifth recess regions R5.

Thereafter, first conductive lines CL1 filling the fifth recess regions R5 may be formed on the first impurity regions IR1. Second conductive lines CL2 filling the fifth recess regions R5 may be formed on the second impurity regions IR2. The first insulating patterns 110 may be interposed between pairs of adjacent first and second conductive lines CL1 and CL2 spaced apart in the second horizontal direction D2.

Referring back to FIGS. 32 and 33, separation structures 130 filling the second trenches T2 may be formed. The stacked structures SS may be defined by the separation structures 130. The stacked structures SS may be formed with the separation structures 130 in between.

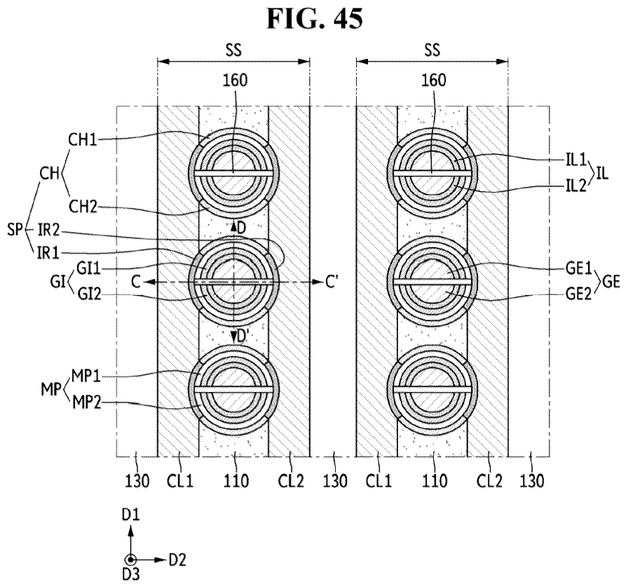

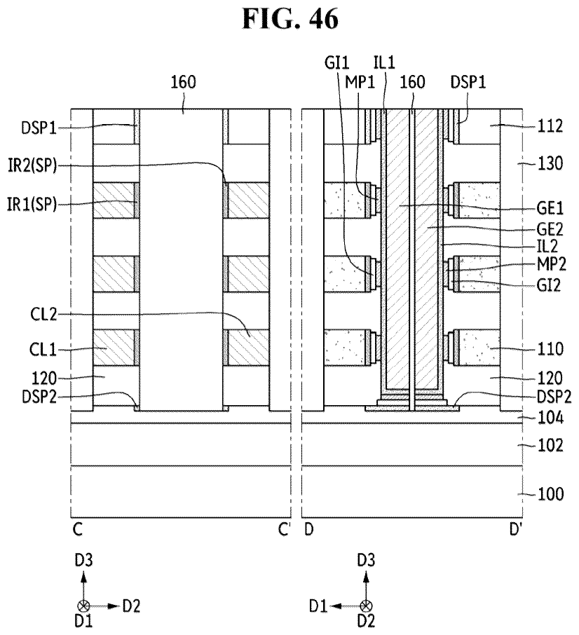

FIG. 45 is a plan view illustrating a semiconductor memory device according to some embodiments. FIG. 46 is a cross-sectional view taken along line A-A′ of FIG. 45. For convenience of explanation, the differences from what has been described above with reference to FIGS. 1 through 9 will be focused on.

Referring to FIGS. 45 and 46, stacked structure SS may include gate electrodes GE, semiconductor patterns SP surrounding the gate electrodes GE, insertion patterns IL interposed between the gate electrodes GE and the semiconductor patterns SP, and gate insulating patterns GI between the insertion patterns IL and the semiconductor patterns SP. The stacked structures SS may not include the metal patterns MP between the insertion patterns IL and the gate insulating patterns GI, as described with reference to FIGS. 1 through 9. The gate insulating patterns GI may be in contact with the insertion patterns IL.

The gate electrodes GE, the semiconductor patterns SP surrounding the gate electrodes GE, and the insertion patterns IL and gate insulating patterns GI interposed between the gate electrodes GE and the semiconductor patterns SP may form ferroelectric FETs.

FIG. 45 is a plan view illustrating a semiconductor memory device according to some embodiments. FIG. 46 is a cross-sectional view taken along lines C-C′ and D-D′ of FIG. 45. For convenience of explanation, the differences from what has been described above with reference to FIGS. 1 through 9 will be focused on.

Referring to FIGS. 45 and 46, stacked structures SS may further include separation insulating patterns 160.

The separation insulating patterns 160 may be disposed within gate electrodes GE, insertion patterns IL, metal patterns MP, gate insulating patterns GI, and semiconductor patterns SP. The separation insulating patterns 160 may extend in the vertical direction D3 and first horizontal direction D1 or second horizontal direction D2. The separation insulating patterns 160 may penetrate the gate electrodes GE, the insertion patterns IL, the metal patterns MP, the gate insulating patterns GI, and the semiconductor patterns SP. The separation insulating patterns 160 may penetrate the bottom portions of the gate electrodes GE and the insertion patterns IL.

The gate electrodes GE may be divided into first gate electrodes GE1 and second gate electrodes GE2 by the separation insulating patterns 160. The insertion patterns IL may be divided into first insertion patterns IL1 and second insertion patterns IL2 by the separation insulating patterns 160. The metal patterns MP may be divided into first metal patterns MP1 and second metal patterns MP2 by the separation insulating patterns 160. The gate insulating patterns GI may be divided into first gate insulating patterns GI1 and second gate insulating patterns GI2 by the separation insulating patterns 160. Channel regions CH of the semiconductor patterns SP may be divided into first channel regions CH1 and second channel regions CH2 by the separation insulating patterns 160.

The first channel regions CH1 and the second channel regions CH2 may be electrically connected to first conductive lines CL1 through first impurity regions IR1, and may be electrically connected to second conductive lines CL2 through second impurity regions IR2. The first channel regions CH1 and the second channel regions CH2 may share first impurity regions IR1, the first conductive lines CL1, second impurity regions IR2, and the second conductive lines CL2.

The first gate electrodes GE1, the first insertion patterns IL1, the first metal patterns MP1, the first gate insulating patterns GI1, and the first channel regions CH1 may form first ferroelectric FETs. The second gate electrodes GE2, the second insertion patterns IL2, the second metal patterns MP2, the second gate insulating patterns GI2, and the second channel regions CH2 may form second ferroelectric FETs. The first ferroelectric FETs and the second ferroelectric FETs may be electrically insulated by the separation insulating patterns 160.

The separation insulating patterns 160 may include, for example, silicon oxide, silicon nitride, and/or silicon oxynitride.

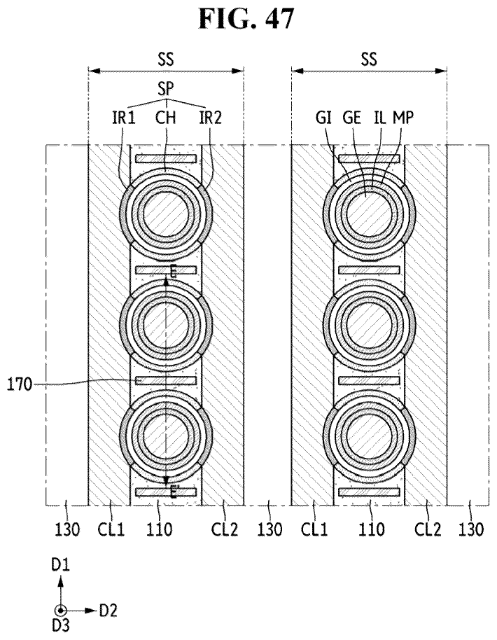

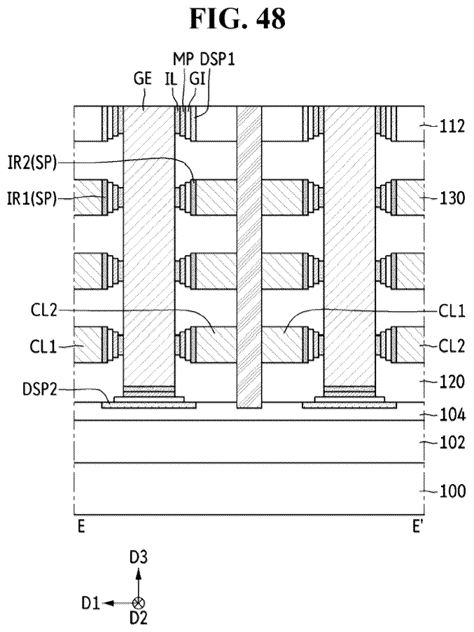

FIG. 47 is a plan view illustrating a semiconductor memory device according to some embodiments. FIG. 48 is a cross-sectional view taken along line E-E′ of FIG. 47. For convenience of explanation, the differences from what has been described above with reference to FIGS. 1 through 9 will be focused on.

Referring to FIGS. 47 and 48, stacked structures SS may further include shielding lines 170.

The shielding lines 170 and gate electrodes GE may be alternately arranged along the first horizontal direction D1. The shielding lines 170 may be disposed between adjacent gate electrodes GE in the first horizontal direction D1. The shielding lines 170 may extend in the vertical direction D3. The shielding lines 170 may penetrate first insulating patterns 110 and second insulating patterns 120.

The shielding lines 170 may include a metal. A ground voltage may be applied to the shielding lines 170. The shielding lines 170 may be used to block electrical interference between the gate electrodes GE and semiconductor patterns SP.

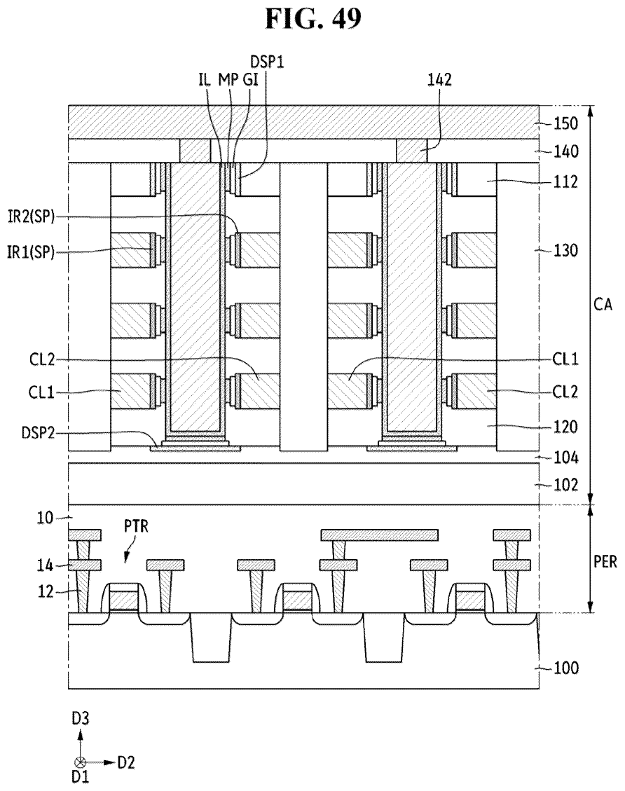

FIGS. 49 through 51 are diagrams illustrating a semiconductor memory device according to some embodiments. For convenience of explanation, the differences from what has been described above with reference to FIGS. 1 through 9 will be focused on.

Referring to FIGS. 49 through 51, the semiconductor memory device according to some embodiments may include a cell array region CA and a peripheral circuit region PER.

The cell array region CA may include the stacked structures SS and the separation structures 130 described with reference to FIGS. 1 through 9. Alternatively, the cell array region CA may include the stacked structures SS and the separation structures 130 described with reference to FIGS. 10 through 14, FIGS. 32 through 34, FIGS. 45 and 46, or FIGS. 47 and 48, or any suitable combination thereof.

The peripheral circuit region PER may include peripheral transistors PTR, peripheral wires 14, peripheral contacts 12, and an interlayer insulating film 10. The interlayer insulating film 50 may cover the peripheral transistors PTR, the peripheral wires 14, and the peripheral contacts 12. The peripheral wires 14 may be provided on the peripheral transistors PTR and may be electrically connected to the peripheral transistors PTR through the peripheral contacts 12. The peripheral wires 14 and the peripheral contacts 12 may each include a conductive material. The interlayer insulating film 50 may include an insulating material.

Referring to FIG. 49, the semiconductor memory device according to some embodiments may have a Cell-on-Peri (COP) structure. The peripheral circuit region PER may be provided on a substrate 100. The peripheral circuit region PER may be interposed between the substrate 100 and a lower insulating film 102. In other words, the peripheral circuit region PER may be provided below the cell array region CA, which includes the stacked structures SS. The peripheral transistors PTR of the peripheral circuit region PER may be formed on the substrate 100.

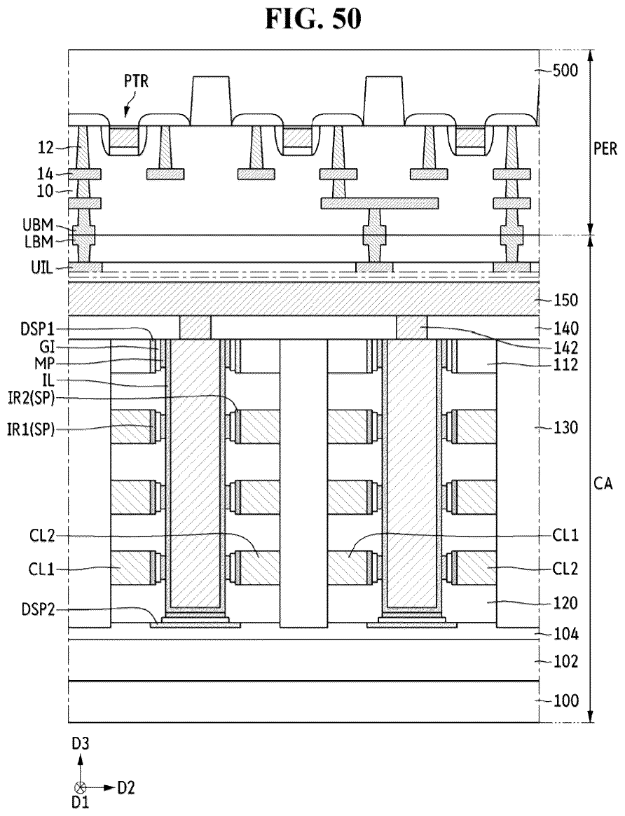

Referring to FIG. 50, the semiconductor memory device according to some embodiments may have a chip-to-chip (C2C) structure. The peripheral circuit region PER may be provided on the cell array region CA. The peripheral circuit region PER may be provided to face the substrate 100. An upper substrate 500 may be positioned at the top and may be exposed to the outside. The peripheral circuit region PER may be provided on the upper substrate 500. Upper wires UIL and lower bonding metals LBM may be provided on the uppermost portion of the cell array region CA. The lower bonding metals LBM may be provided on the respective upper wires UIL.

The upper substrate 500 may include a semiconductor substrate, such as an Si substrate, a Ge substrate, or an SiGe substrate.

Upper bonding metals UBM may be provided on the lowermost portion of the peripheral circuit region PER. The upper bonding metals UBM may be connected to the respective peripheral wires 14. The lower bonding metals LBM may be connected to the respective upper bonding metals UBM by metal bonding. For example, the metal bonding may be Cu—Cu bonding. By connecting the lower bonding metals LBM to the upper bonding metals UBM, the cell array region CA and the peripheral circuit region PER may be electrically connected.

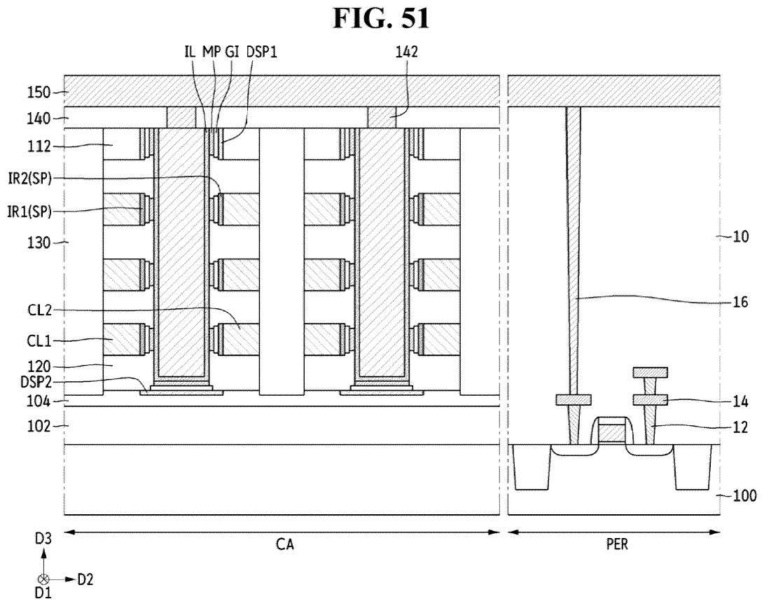

Referring to FIG. 51, the peripheral circuit region PER may be provided on the substrate 100. The peripheral circuit region PER may be spaced apart from the cell array region CA in a horizontal direction (for example, in the second horizontal direction D2). The peripheral circuit region PER may be provided on the substrate 100.

Wires 150 may extend from the cell array region CA to the peripheral circuit region PER. The peripheral wires 14 may be electrically connected to the wires 150 through through-vias 16.

Embodiments of the present disclosure have been described with reference to the accompanying drawings. However, the invention is not limited to the described embodiments, and various modifications and other forms can be made without departing from the scope and spirit of the present disclosure by those skilled in the art. Therefore, the above-described embodiments should be understood as illustrative rather than restrictive in all respects.

What is claimed is:

1. A semiconductor memory device comprising:
a first conductive line extending in a first horizontal direction parallel to an upper surface of a substrate;
a second conductive line spaced apart from the first conductive line in a second horizontal direction, the second conductive line extending in the first horizontal direction, and the second horizontal direction being parallel to the upper surface of the substrate and intersecting the first horizontal direction;
a gate electrode extending in a vertical direction perpendicular to the upper surface of the substrate and between the first conductive line and the second conductive line;
a semiconductor pattern extending in the vertical direction and surrounding side surfaces of the gate electrode, the semiconductor pattern being electrically connected to the first conductive line and the second conductive line;
an insertion pattern extending in the vertical direction and between the gate electrode and the semiconductor pattern, the insertion pattern comprising a ferroelectric material;
a metal pattern extending in the vertical direction and between the insertion pattern and the semiconductor pattern; and
a gate insulating pattern extending in the vertical direction and between the metal pattern and the semiconductor pattern,
wherein an area of the insertion pattern in contact with the metal pattern is smaller than an area of the gate insulating pattern in contact with the semiconductor pattern.

2. The semiconductor memory device of claim 1, wherein a length of the insertion pattern in contact with the metal pattern is smaller than a length of the gate insulating pattern in contact with the semiconductor pattern.

3. The semiconductor memory device of claim 1, wherein a length of the gate insulating pattern in the vertical direction is smaller than a length of the semiconductor pattern in the vertical direction.

4. The semiconductor memory device of claim 1, wherein a length of the metal pattern in the vertical direction decreases closer to the insertion pattern.

5. The semiconductor memory device of claim 1, wherein a length of the gate insulating pattern in the vertical direction decreases closer to the insertion pattern.

6. The semiconductor memory device of claim 1, wherein the gate insulating pattern disposed on an upper surface, a lower surface, and side surfaces of the metal pattern, and
wherein the semiconductor pattern is disposed on the gate insulating pattern.

7. The semiconductor memory device of claim 1, wherein the metal pattern includes a different material from the gate electrode.

8. The semiconductor memory device of claim 1, further comprising:
a separation insulating pattern extending in the vertical direction and penetrating the gate electrode, the insertion pattern, the metal pattern, the gate insulating pattern, and the semiconductor pattern.

9. The semiconductor memory device of claim 1, further comprising:
a shielding line extending in the vertical direction and spaced apart from the gate electrode in the first horizontal direction.

10. The semiconductor memory device of claim 1, further comprising:
a dummy semiconductor pattern disposed on a lower surface of the gate electrode,
wherein the insertion pattern further extends along the lower surface of the gate electrode, and
wherein the metal pattern and the gate insulating pattern are disposed between the dummy semiconductor pattern and the insertion pattern on the lower surface of the gate electrode.

11. The semiconductor memory device of claim 1, wherein the insertion pattern comprises different first ferroelectric patterns and second ferroelectric patterns.

12. The semiconductor memory device of claim 1, wherein the insertion pattern comprises a ferroelectric pattern and a dielectric pattern.

13. A semiconductor memory device comprising:
first conductive lines and first insulating patterns alternately stacked in a vertical direction perpendicular to an upper surface of a substrate;
a gate electrode extending in the vertical direction;
a plurality of semiconductor patterns surrounding side surfaces of the gate electrode, each semiconductor pattern among the plurality being spaced apart in the vertical direction;
insertion patterns between the gate electrode and the plurality of semiconductor patterns;
a plurality of metal patterns between the insertion patterns and the plurality of semiconductor patterns such that a respective metal pattern is between the insertion pattern and a respective semiconductor pattern; and
a plurality of gate insulating patterns between the plurality of metal patterns and the plurality of semiconductor patterns such that a respective gate insulating pattern is between the respective metal pattern and the respective semiconductor pattern,
wherein the first insulating patterns extend between the semiconductor patterns,
wherein the semiconductor patterns are electrically connected to the respective first conductive lines, and
wherein a length of the insertion patterns in contact with the metal patterns is smaller than a length of the gate insulating patterns in contact with the semiconductor patterns.

14. The semiconductor memory device of claim 13, further comprising:
second conductive lines spaced apart from the first conductive lines in a horizontal direction parallel to the upper surface of the substrate; and
second insulating patterns filling spaces between adjacent first insulating patterns in the vertical direction,
wherein the semiconductor patterns are electrically connected to respective second conductive lines, and
wherein the second insulating patterns comprise a different material from the first insulating patterns.

15. The semiconductor memory device of claim 13, wherein the insertion patterns extend in the vertical direction and are between the first insulating patterns and the gate electrode.

16. The semiconductor memory device of claim 15, wherein the respective gate insulating pattern of the plurality of gate insulating patterns extend in the vertical direction between the first insulating patterns and the insertion patterns.

17. The semiconductor memory device of claim 13, wherein the first insulating patterns extend in the vertical direction between adjacent metal patterns, and wherein the first insulating pattern further extends in the vertical direction between adjacent gate insulating patterns.

18. A semiconductor memory device comprising:
a first conductive line extending in a first horizontal direction parallel to an upper surface of a substrate;
a second conductive line spaced apart from the first conductive line in a second horizontal direction, the second horizontal direction also being parallel to the upper surface of the substrate and intersecting the first horizontal direction, the second conductive line extending in the first horizontal direction;
gate electrodes spaced apart in the first horizontal direction and extending in a vertical direction perpendicular to the upper surface of the substrate between the first conductive line and the second conductive line;
a respective semiconductor pattern extending in the first horizontal direction, surrounding side surfaces of each of the gate electrodes, and electrically connected to the first conductive line and the second conductive line;
a respective insertion pattern between each of the gate electrodes and the respective semiconductor pattern, the respective insertion pattern comprising a ferroelectric material;
a respective metal pattern between the respective insertion pattern and the respective semiconductor pattern; and
a respective gate insulating pattern between the respective metal pattern and the respective semiconductor pattern,
wherein an area of the respective insertion pattern in contact with the respective metal pattern is smaller than an area of the respective gate insulating pattern in contact with the respective semiconductor pattern.

19. The semiconductor memory device of claim 18, wherein the respective gate insulating pattern extends along an upper surface, a lower surface, and side surfaces of the respective metal pattern, and
wherein the semiconductor pattern extends along the gate insulating pattern.

20. The semiconductor memory device of claim 18, wherein a length of the respective insertion pattern in contact with the respective metal pattern is smaller than a length of the respective gate insulating pattern in contact with the respective semiconductor pattern.
